(19) United States
(12) Patent Application Publication
(10) Pub. No.: US 2011/0032780 A1
(43) Pub. Date: Feb. 10, 2011

(54) Semiconductor device

(75) Inventors: Kazuhiro TERAMOTO, Tokyo (JP); Takuyo KODAMA, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/805,510

(22) Filed: Aug. 3, 2010

(30) Foreign Application Priority Data
Aug. 6, 2009 (JP) 2009-183502

(51) Int. Cl. G11C 7/10; G11C 7/06

(52) U.S. Cl. 365/189.18; 365/205

(57) ABSTRACT

The semiconductor device includes a first pair of data lines, a second pair of data lines, a third pair of data lines, a first amplifier (SA) connected to the first pair of data lines, a first switch that controls connection between the first pair of data lines and the second pair of data lines, a second switch that controls connection between the second pair of data lines and the third pair of data lines, a second amplifier that amplifies data on the second pair of data lines, for output to the third pair of data lines, a third amplifier connected to the third pair of data lines, and a control circuit that controls the second switch forming a pair of switches. When two data lines constituting the third pair of data lines both assume a first state, the control circuit controls the second switch to be turned off, thereby controlling the second pair of data lines and the third pair of data lines to be disconnected. Output data of the first amplifier is then output to the second pair of data lines via the first switch. When the two data lines constituting the third pair of data lines assume a second state different from the first state according to data output from the third amplifier, the second switch is controlled to be turned on, thereby controlling the second pair of data lines and the third pair of data lines to be connected. Then, the first amplifier receives the data output from the first amplifier.

### TECHNICAL FIELD

### CROSS-REFERENCE TO RELATED APPLICATION

This application is based upon and claims the benefit of the priority of Japanese patent application No. 2009-183502 filed on Aug. 06, 2009, the disclosure of which is incorporated herein in its entirety by reference thereto.

The present invention relates to a semiconductor device, more specifically, the invention relates to a semiconductor device including a switch control function between hierarchical data buses.

### BACKGROUND

In recent years, the integration density of a DRAM (Dynamic Random Access Memories) device has been increased from 512 M bits to 1G bits, and to 2G bits and a fine fabrication process has been in progress.

In accordance with the lowering of voltage of DRAM products, a supply voltage of a memory cell array has been reduced from 1.8V to 1.4 V, to 1.2V, and further to 1.0V.

In a sense amplifier that amplifies a signal on a bit line in a DRAM, the reduction of a transistor on-current is remarkable owing to the reduction of the size of the sense amplifier caused by the progress of shrinkage in transistor dimension and the reduction of a gate-to-source voltage Vgs of a transistor caused by the lowering of the array voltage. That is, due to the progress of shrinkage in dimension and the voltage lowering, a current driving capability of the sense amplifier has been significantly reduced.

As an input/output data transfer system in a memory array in the DRAM, a hierarchical I/O system has been employed.

### <Hierarchical I/O System>

As shown in FIG. 3, this system includes LIO lines (local input/output lines) (LIOT, LIOB) to which a plurality of sense amplifiers (SAs) are connected and MIO lines (main input/output lines) (MIOT, MIOB) which is connected to a main amplifier (MA). Each of the sense amplifiers (SAs) is connected to a pair of bit lines (BLT, BLB). At each connection section (SWC) between corresponding ones of the LIO lines and the MIO lines, a pass gate (also referred to as a transfer gate), which is controlled to be turned on (conductive) or turned off (non-conductive) by a MAT selection signal that selects a memory mat is provided. When a read access from memory cell data is executed, a sense amplifier selected by a column selection signal (YS) extracts electric charge on the LIO line, the pass gate provided in the connection section (SWC), and the MIO line, thereby generating a minute voltage difference (Vsig) between a pair of MIO lines of MIOT and MIOB. This minute voltage difference (Vsig) is amplified by the main amplifier (MA), and driven and output to a data transfer bus (RWBUS: outside the hierarchical I/O system) by a bus driver (BUSD) 301.

As described above, the reduction of the on-current of the sense amplifier caused by the progress of shrinkage in dimension and the voltage reduction, the time needed for extracting electric charge on the LIO and MIO lines by the sense amplifier has become long.

Further, due to enhanced integration density, the load capacitance of an MIO line has been increasing. Moreover, the data rate of the DRAM product is increased from DDR (Double Data Rate) 1, to DDR 2, and to DDR3. Thus, it has become important to speed up data transfer in the memory array.

<Hierarchical I/O System using Sub-Amplifiers>

For this reason, the following circuit system has been widely used. In this system, an amplifier circuit (referred to as a “sub-amplifier” (Sub-Amp)) is arranged at the SWC, wherein electric charge stored in a capacitance of the LIO line is discharged by the sense amplifier (SA) and electric charge on the MIO line is discharged by the sub-amplifier at the SWC. With this load distribution scheme, the high speed circuit system is implemented.

In such a circuit system, when a write to a memory cell is performed, it is common to perform the write operation via the pass gate arranged at the SWC. It is because, since the write is performed by a driver circuit (having a large driving capability), which is a so-called write driver arranged in a main amplifier (MA) unit, electric charge on the MIO, LIO, and bit lines can be discharged at high speed.

As another system of a write circuit in the hierarchical I/O system using the sub-amplifiers, a configuration as shown in FIG. 9 is known. In this configuration, gates that drive a pair of LIO lines are controlled by data on a MIO line. The pair of LIO lines is driven by NMOS transistors 1201 and 1202 and PMOS transistors 1203 and 1204. When a write enable signal DIOWEB is active (Low) and the MIO line MIOB is Low, an output of an NOR circuit 1205 goes High. Then, the NMOS transistor 1201 is made conductive, the PMOS transistor 1204 is made conductive, and the LIO lines LIOB and LIOT are respectively set to Low and to High. In the case of the configuration in FIG. 9, sizes of the MOS transistors 1201, 1202, 1203, and 1204 that drive the pair of LIO lines need to be increased.

For this reason, it is difficult to lay out the circuit in FIG. 9 in a limited SWC region. Arranging the circuit in FIG. 9 in the SWC region may bring about the increase of the chip area.

<Hierarchical I/O using Pass Gate System>

Next, a write operation using a pass gate system will be described below using FIGS. 1, 3, 4, 5, 6, and 8.

### <Configuration of Common DRAM>

FIG. 1 is a block diagram showing a configuration of a common

DRAM. The DRAM includes a memory array 1, an X decoder and X timing generation circuit 2, a Y decoder and Y timing generation circuit 3, a decoder control circuit 4, a DLL (Delay Locked Loop: delay locked loop) 9, a data latch circuit 5, an input/output interface 6, an internal clock (CLK) generation circuit 7, and a control signal generation circuit 8. The memory cell array 1 includes banks 0 to m. Each bank includes memory mat rows 1, 2, and 3. A bank configuration, a memory mat configuration within the bank, and the like are not of course limited to such configurations.

The control signal generation circuit 8 receives command signals (/CS (chip select), /RAS (row address strobe), /CAS (column address strobe), and /WE (write enable)), decodes the command signals, generates control signals according to a decoded result of the command, and outputs the generated control signals to the X decoder and X timing generation circuit 2, Y decoder and Y timing generation circuit 3, decoder control circuit 4, and the like. A symbol “/” before the name of a signal indicates that the signal is active when it assumes a Low level. A row address of an input address signal (ADD) is decoded by the X decoder 2, and a word line WL is selected by a sub-word driver (SWD). When the word line WL is selected, data is read out to a corresponding bit line (BL) from a corresponding memory cell (MC), and is amplified by a corresponding sense amplifier (SA). A column address of the address signal (ADD) is decoded by the Y decoder 3, a selected column selection signal is set active to select the bit line (BL) and the sense amplifier (SA).

An output (read data) amplified by the sense amplifier (SA) is transferred to the data latch circuit 5 and the input/output interface 6, and is output to an outside through a DQ pin. DQ in FIG. 1 indicates a plurality of data I/O terminals (DQ pins).

Data strobe signals DQS and /DQS is a trigger signal for latching data when the data is received from the outside.

A data mask signal DM is a control signal for masking data. When the data mask signal DM is set to High simultaneously with data received, the memory cell write of the data is masked (inhibited), so that the write is not performed. A terminal for the data mask signal DM is an external terminal of the semiconductor device. A plurality of external terminals are provided for the data mask signals DM. Each data mask signal DM is associated with one of a plurality of groups formed by corresponding ones of the DQ terminals.

When data is written into a memory cell, the data mask signal DM is set to Low, and the data is supplied to the DQ pin. The write data is transferred to the corresponding sense amplifier (SA) through the input/output interface 6 and the data latch circuit 5.

The corresponding sense amplifier (SA) drives the corresponding bit line (BL) in accordance with the write data, and writes the data into the memory cell connected to the corresponding bit line (BL) and the selected word line.

<Configuration Examples of Sense Amplifier and Bit line System>

FIG. 2 is a diagram showing a typical configuration example of the sense amplifier (SA). FIG. 2 shows a bit line system part for a shared-type sense amplifier (SA) circuit. Each word line is driven by a sub-word driver circuit 14. Each memory cell includes an NMOS transistor that has a gate electrode connected to the corresponding word line and a drain or a source thereof connected to the corresponding bit line, and a capacitor Cs that has one end thereof connected to the source or drain of the NMOS transistor and the other end thereof connected to a power supply (plate electrode). Though not limited thereto, a bit line structure in FIG. 2 has folded type bit lines in which a memory cell MC shown and connected to the corresponding word line is connected to the bit line BLT and a memory cell not shown and connected to the word line adjacent to the corresponding word line is connected to the bit line BLB that is complementary with the bit line BLT. The sense amplifier (SA) circuit connected between the pair of bit lines (BLT/B) includes a PMOS transistor pair that have sources connected in common to a PCS line and have gates and drains cross-connected, and an NMOS transistor pair that have sources connected in common to an NCS line and have gates and drains cross connected. The drains of the PMOS transistor pair and the drains of the NMOS transistor pair are respectively connected. The drains of the PMOS transistor pair and the NMOS transistor pair are connected to the pair of bit lines (BLT/B). The pair of bit lines BLT and BLB of True and Bar is represented by BLT/B as well.

Referring to FIG. 2, the pair of bit lines (BLT/BLB) of a memory mat 0 (11) shown on an upper side of FIG. 2 and the pair of bit lines (BLT/BLB) of a memory mat 1 (13) shown on a lower side of FIG. 2 share a sense amplifier (SA) 12 arranged therebetween. Pass transistors (NMOS transistors) which are controlled to be made conductive or non-conducive by a control signal SHRB0 are provided between the pair of bit lines on the side of the memory mat 0(11) and the sense amplifier circuit (SA circuit). Pass transistors (NMOS transistors) which are controlled to be made conductive or non-conducive by a control signal SHRB1 are provided between the pair of bit lines on the side of the memory mat 1(13) and the sense amplifier (SA).

A circuit including three NMOS transistors that have gates connected to a control signal BLEQT0 and that are controlled to be made conductive or non-conductive by the control signal BLEQT0 is provided for the pair of bit lines BLT/B on the side of the memory mat 0 (11). When the circuit is made conductive, the circuit precharges the pair of bit lines BLT/B of the memory mat 0 (11) from a precharge power supply, and equalizes the pair of bit lines BLT/B.

Similarly, a circuit including three NMOS transistors that have gates connected to a control signal BLEQT1 and are controlled to be made conductive or non-conductive by the control signal BLEQT1 is provided for the pair of bit lines BLT/B on the side of the memory mat 1 (13). When the circuit is made conductive, the circuit precharges the pair of bit lines BLT/B of the memory mat 1 (13) from the precharge power supply, and equalizes the pair of bit lines BLT/B.

The drain pairs of the PMOS transistor pair and the NMOS transistor pair of the sense amplifier (SA) are connected in common to an pair of IO lines (pair of LIO lines) via a column switch pair, which is controlled to be made conductive or non-conducive by the column selection signal YS.

A PMOS transistor 18 that receives a control signal RSAEP1T at a gate thereof is provided between a VARY power supply line of a memory array power supply and the PCS line. An NMOS transistor 20 that receives a control signal RSAENT at a gate thereof is provided between a VSSSA power supply line and the NCS line. Between the PCS and NCS lines, there are provided a precharge and equalization circuit 19 that are made conductive when a control signal EQCS is High are provided. The precharge and equalization circuit 19 precharges and equalizes the PCS and NCS lines.

### <Configuration Example of Hierarchical I/O System>

FIG. 3 is a diagram schematically showing a configuration of a data transfer system (hierarchical I/O system) in the memory array 1 in FIG. 1. Referring to FIG. 3, reference symbol RWSBUS indicates a bus for performing data transfer within a chip. A bus driver (BUSD) <k> 301 is a kth bus driver circuit connected to the RWBUS bus. A main amplifier circuit (MA) <k> 302 for amplifying data on the pair of MIO lines (complementary MIOT and MIOB lines) is connected to the bus driver circuit <k> 301.

The main amplifier circuit <k> 302 is connected to a kth pair of MIO lines of MIOT<k> and MIOB<k> in the array. The main amplifier circuit (MA) <k> 302 is differentially connected to the pair of MIO lines of MIOT<k> and MIOB<k> and is connected to the bus driver (BUSD) <k> 301. When a write is performed, the main amplifier circuit (MA) <k> 302 receives an output of the bus driver (BUSD) <k> 301 and outputs differential output signals to the pair of MIO lines of MIOT<k> and MIOB<k>. When a read is performed, the main amplifier circuit (MA) <k> 302 differentially receives signals on the pair of MIO lines of MIOT<k> and MIOB<k>, converts the signals to a CMOS level, and outputs the CMOS level to the bus driver (BUSD) <k> 301.

To the pair of MIO lines (of MIOT<k> and MIOB<k>), (m+1) SWC circuits 303 (SWC<0> to SWC<m>) are connected. The SWC is a cross section between the pair of MIO lines and the pair of LIO lines.

A logic is formed so that the SWC circuit corresponding to a row of sense amplifiers SA<0>, SA<1>, SA<0>, . . . and SA<n> for reading data is selected from the (m+1) SWC circuits 303 (SWC<0> to SWC<m>) based on the word line WL selected by decoding a row address signal, and-the other SWC circuits are not selected.

The SWC circuit SWC<0> is connected to the pair of LIO lines of LIOT<0> and LIOB<0>. The SWC circuit SWC<1> is connected to the pair of LIO lines of LIOT<1> and LIOB<1>. Likewise, the SWC circuit SWC<m> is connected to the pair of LIO lines of LIOT<m> and LIOB<m>.

Referring to FIG. 3, when the word line WL is selected, the SWC circuit SWC<0> (303) is selected. Connection of each LIO line to (n +1) sense amplifiers SA<0> to SA<n> is made according to (n+1) column selection signals YS<0> to YS<n>. One selected sense amplifier SA is connected.

Schematic configurations of the main amplifier (MA) <k> 302, an SWC circuit SWC<i> 303 (i=1 to m), and a sense amplifier (SA) <j> 304 (j=1 to n) are respectively shown in FIGS. 8, 4, and 5.

FIG. 8 shows only a circuit configuration of a write (Write) amplifier in the main amplifier (MA) 302 in FIG. 3, and does not show a read (READ) amplifier.

### <Main Amplifier: Write Amplifier>

Referring to FIG. 8, the write amplifier of the main amplifier (MA) includes: PMOS transistors 901 and 902 that are connected in series between the pair of MIO lines MIOB and MIOT, have a connection node thereof connected to a VIO terminal, and respectively receive signals DWAEOP and DWAE1P at gates thereof;

NMOS transistors 903 and 904 that are connected between the pair of MIO lines MIOB and MIOT, have a connection node thereof connected to a low-potential power supply VSS, and respectively receive signals DWAE1N and DWAE0N at gates thereof;

PMOS transistors 905 and 906 that are connected between the pair of MIO lines MIOB and MIOT, have a connection node thereof connected to the VIO terminal (precharge power supply terminal), and receive in common a signal DMIOEQB (MIO line precharge/equalize control signal) at gates thereof; and

a PMOS transistor 907 that is connected between the pair of MIO lines MIOB and MIOT, and that receives the signal DMIOEQB at a gate thereof.

The PMOS transistors 905, 906, and 907 constitute a precharge/equalization circuit, which precharges and equalizes the pair of MIO lines MIOB and MIOT to a precharge power supply voltage VIO before a write.

The PMOS transistors 901 and 902 and the NMOS transistors 903 and 904 in the main amplifier (MA) in FIG. 8 are WRITE transistors. At a time except a write operation, the gate input signals DWAE0P and DWAE1P are set to be High, and the gate input signals DWAE0N and DWAE1N are set to be Low. These transistors are thereby kept non-conductive.

When the write is performed so that the MIO line MIOT is set to High and the MIO line MIOB is set to Low, the signal DWAE1P is set to Low, the signal DWAE0P is set to High, the signal DWAE0N is set to Low, and the signal DWAE1N is set to High. On the contrary, when the write is performed so that the MIO line MIOB is set to High and the MIO line MIOT line is set to Low, the signal DWAE0P is set to Low, the signal DWAE1P is set to High, the signal DWAE1N is set to Low, and the signal DWAE0N is set to High.

In case of a read operation and in case of data masking in a write operation, the signals DWAE0P and DWAE1P are set to High, and the signals DWAE1N and DWAE0N are set to Low.

Referring again to FIG. 3 again, when the word line WL is selected, n items of data from n memory cells connected to the word line WL are read respectively into the sense amplifiers SA<0>, SA<1>, . . . and SA<n> as minute voltage difference. The sense amplifier circuits SA<0>, SA<1>, . . . and SA<n> are set to have a same configuration such as a circuit configuration shown in FIG. 5.

### <Configuration Example of Sense Amplifier>

In the sense amplifier (SA) shown in FIG. 5, reference symbols PCS and NCS are signals that control activation of the sense amplifier (refer to FIG. 2). Before activation, the signals PCS and NCS are precharged to a voltage that is the same as a precharge voltage of the pair of bit lines BLT/B. This sense amplifier circuit is set to have the same configuration as the configuration of the sense amplifier circuit in FIG. 2.

Referring to FIG. 5, the sense amplifier includes PMOS transistors 506 and 505 that have sources connected to the PCS line and drains connected to the bit lines BLT and BLB, respectively, and NMOS transistors 504 and 503 that have drains connected to the drains of the PMOS transistors 505 and 506, sources connected to the NCS line, and gates respectively connected to the drains of the PMOS transistors 505 and 506. When the PCS line assumes a High level and the NCS line assumes a Low level, the sense amplifier is operated. When the bit line BLT is higher than the threshold voltage of the NMOS transistor 503 and the bit line BLB is lower than a potential obtained by subtracting the absolute value of threshold value of the PMOS transistor 506 from a High level, the NMOS transistor 503 is made conductive, and the PMOS transistor 506 is made conductive, as a result of which the bit lines BLT and BLB are respectively set and kept at the High level and a Low level. On the contrary, when the bit line BLB is higher than the threshold voltage of the NMOS transistor 504 and the bit line BLB is lower than a potential obtained by subtracting the absolute value of the threshold of the PMOS transistor 505 from the High level, the NMOS transistor 504 is made conductive and the PMOS transistor 505 is made conductive, as a result of which the bit lines BLT and BLB are respectively set and kept at the Low and High levels, respectively.

Referring to FIG. 5, NMOS transistors 502 and 501 that have gates connected to the column selection signal YS constitute column switches (Y switches). The NMOS transistor 502 is connected between the bit line BLT and the LIO line LIOT, and the NMOS transistor 501 is connected between the bit line BLB and the LIO line LIOB.

After a minute voltage difference has been generated between the pair of bit lines BLT/B, the sense amplifier (SA) respectively varies the PCS line and the NCS line to a memory cell array voltage VARY and the ground voltage VSS, thereby amplifying this minute voltage difference.

### <Configuration Example of SWC Circuit>

FIG. 4 is a diagram showing a configuration example of the SWC circuit 303 in FIG. 3. The SWC<0> to SWC<m> circuits in FIG. 3 are set to have the same configuration. Referring to FIG. 4, the SWC circuit includes: a pass gate (CMOS transfer gate) 401 that is connected between the MIO line MIOB and the LIO line LIOB, and that includes PMOS and NMOS transistors that receive the write mode signal DIOWEB and a signal obtained by inverting the signal DIOWEB by an inverter 400 at gates thereof, respectively, a pass gate (CMOS transfer gate) 402 that is connected between the MIO line MIOT and the LIO line LIOT and that includes PMOS and NMOS transistors that receive the signal DIOWEB and the signal obtained by inverting the signal DIOWEB by the inverter 400 at gates thereof, respectively, an NMOS transistor 407 that has a drain connected to the MIO line MIOT and a gate connected to the LIO line LIOB, an NMOS transistor 403 that has a drain connected to a source of the NMOS transistor 407 and a source connected to the power supply VSS, an NMOS transistor 406 that has a drain connected to the MIO line MIOB and a gate connected to the LIO line LIOT, an NMOS transistor 404 that has a drain connected to a source of the NMOS transistor 406 and a source connected to the power supply VSS, an NMOS transistor 405 that is connected between the sources of the NMOS transistor 407 and the NMOS transistor 406 that have gates connected in common to a signal line DIORET together with gates of the NMOS transistors 403 and 404, PMOS transistors 408 and 409 that are connected between the pair of LIO lines LIOT and LIOB, and that have gates connected to a precharge/equalize signal DIOEQB and have a common connection node of thereof connected to the VIO terminal; and a PMOS transistor 410 that is connected between the LIO lines LIOT and LIOB, and that has a gate connected to the precharge/equalize signal DIOEQB.

An operation of reading from a memory cell or writing to a memory cell is performed after the sense amplifier (SA) has amplified the minute voltage difference between the pair of bit lines BLT/B.

Before each of read and write operations is performed, the signal DMIOEQB is set to Low and the pair of main input/output lines MIOT/B is precharged to a VIO voltage in the write amplifier in FIG. 8. The signal DIOEQB shown in FIG. 4 is also Low, and the pair of local input/output lines LIOT/B is also similarly precharge/equalized to the VIO voltage.

The signal DIOWEB in the SWC circuit shown in FIG. 4 is High (deactivated) and the pass gates (CMOS transfer gates) 401 and 402 that connect the pair of MIO lines MIOT/B and the pair of LIO lines LIOT/B are made non-conductive (turned off). A DIORET signal is Low and the NMOS transistors 403, 404, and 405 in the sub-amplifier for reading in the SWC circuit are all made non-conductive.

When a READ command or a WRITE command is supplied, the signals DMIOEQB and DIOEQB from the control signal generation circuit 8 in FIG. 1 both go High. The pair of MIO lines MIOT/B and the pair of LIO lines LIOT/B assume a floating state.

### <READ Operation>

First, a read operation will be briefly described. A column address received simultaneously with reception of the READ command is decoded by the Y decoder (refer to FIG. 1), and one column selection signal YS of the (n+1) column selection signals YS<0> to YS<n> is selected for one pair of LIO lines.

When the column selection signal YS goes High, the NMOS transistors 501 and 502 are made conductive in the sense amplifier circuit in FIG. 5. Electric charge on the LIO line (LIOT or LIOB) connected to the bit line (BLT or BLB) in a Low state discharged. A voltage difference is thereby generated between LIOT and LIOB.

When the difference in voltage-level is generated between LIOT and LIOB, a difference is generated between gate voltages of the NMOS transistors 406 and 407 which have gates respectively connected to the pair of LIO lines LIOT and LIOB and which have the drains respectively connected to the pair of MIO lines MIOB and MIOT. When the DIORET signal in FIG. 4 is transitioned to High in this state, the NMOS transistors 403, 404, and 405 are all made conductive. Source voltages of the NMOS transistors 406 and 407 assume the low-potential power supply voltage VSS.

At this point, the gate-to-source voltage Vgs of each of the NMOS transistors 406 and 407 assumes a positive voltage (threshold voltage or higher), the NMOS transistors 406 and 407 are both made conductive. Due to the difference in voltage-level generated between the LIO lines LIOT and LIOB, the gate-to-source voltages Vgs of the transistors 406 and 407 become different. A difference is generated between on currents (drain-to-source currents) that flow from the drains to the sources of the NMOS transistors 406 and 407. As a result, a difference is generated between electric charge of the MIOB and MIOT that are respectively discharged by the NMOS transistors 406 and 407 at a same time. A difference in voltage-level is generated between the MIOT and MIOB.

When the LIOT assumes a higher voltage than the LIOB, a drain current of the NMOS transistor 406 becomes larger than a drain current of the NMOS transistor 407. The MIOB is discharged more than the MIOT, so that the MIOB assumes a lower voltage than the MIOT. On the other hand, when the LIOB assumes a higher voltage than the LIOT, the drain current of the NMOS transistor 407 becomes larger than the drain current of the NMOS transistor 406. The MIOT is discharged more than the MIOB, so that the MIOT assumes a lower voltage than the MIOB.

A difference in voltage-level between the MIOT and MIOB driven by the NMOS transistors 406 and 407 is amplified up to a CMOS amplitude by the main amplifier (MA) in FIG. 3.

By arranging the sub-amplifier circuit for reading (composed by the transistors 406, 407, 403, 404, and 405 in FIG. 4) between the pair of LIO lines LIOT/B and the pair of MIO lines MIOT/B in the SWC circuit 303 in FIG. 3 as described above, the sense amplifier (SA) should extract only electric charges of the pair of LIO lines LIOT/B. Even the sense amplifier (SA) having a small current driving capability can perform a high-speed read operation.

However, since the sub-amplifier circuit (SWC) shown in FIG. 4 are composed by the NMOS transistors 406 and 407 that have gates respectively connected to the LIOT and LIOB, data transfer from the MIO line (MIOT/B) to the LIO line (LIOT/B) cannot be performed.

For this reason, for transfer of WRITE data, the pass gates (401, 402 in FIG. 4) are used. By causing the pass gates to be conductive, the data is transferred from the pair of MIO lines MIOT/B to the pair of LIO lines LIOT/B.

### <Write Operation>

A write operation in the circuit configurations shown in FIG. 3 (about the hierarchical I/O system), FIG. 8 (about the write amplifier), FIG. 4 (about the SWC circuit), and FIG. 5 (about the sense amplifier) will be described using a timing waveform diagram in FIG. 6. FIG. 6 is prepared by the inventors of the present invention, for description of the operation.

First, before the write operation, the pair of MIO lines MIOT/B and the pair of LIO lines LIOT/B are precharged to the VIO voltage.

Before the WRITE command is received, the signal DMIOEQB (in FIG. 8) and the signal DIOEQB (in FIG. 4) respectively go High, and the pair of MIO lines MIOT/B and the pair of LIO lines LIOT/B assume the floating state.

When the signal DIOWEB transitions to Low (as shown in FIG. 6A), the pass gates 401 and 402 shown in FIG. 4 are made conductive, and the LIO lines and the MIO lines are connected.

Then, in case of writing data 0, the signal DWAE0P goes Low, and the signal DWAE0N goes High (the signal DWAE1P goes High, and the signal DWAE1N goes Low) in the write amplifier in FIG. 8. Then, the PMOS transistors 901 and 902 are made conductive and non-conductive, and the NMOS transistor 904 is made conductive. The MIOT transitions to a Low level, and the MIOB transitions to a High level.

In case of writing data 1, the signal DWAE1P goes Low, and the signal DWAE1N goes High (the signal DWA0P goes High and the signal DWAE0N goes Low) in the write amplifier in FIG. 8. Then, the NMOS transistor 903 is made conductive, the PMOS transistor 902 is made conductive, the MIOB transitions to the Low level, and the MIOT transitions to the High level (as shown in FIG. 6B).

Electric charge of the LIO line is discharged to the MIO line via the pass gates 401 and 402 in the SWC circuit in FIG. 4 (as shown in FIG. 6C).

After the voltages of the LIO lines have been settled, the voltage of a YS line corresponding to the pair of bit lines BLT/B connected to a memory cell to be written is set to High, and data is written into the bit lines and the memory cell (as shown in FIG. 6D).

In the example shown in FIG. 6D, the pair of bit lines BLT/B is kept to be in a state where the voltages of the BLT and BLB are amplified to the High level and the Low level by the sense amplifier (SA) that amplifies the data for the selected memory cell (to which the word line connected is High) output to the pair of bit lines BLT/B, at a time before the High pulse of the YS line rises. Then, due to the High pulse of the YS line, the switches 501 and 502 (in FIG. 5) are made conductive, the pair of LIO lines LIOT/B and the pair of bit lines BLT/B are electrically connected, and the sense amplifier (SA) drives the pair of bit lines BLT/B using the complementary data from the pair of LIO lines LIOT/B. The data is thereby written to the selected memory cell. Then, after the word line has been set from High to Low, a High pulse is supplied to the signal BLEQT0 or BLEQT1 in FIG. 2, and the pair of bit lines BLT/B is precharged/equalized.

Patent Document 1 discloses the following configuration. In this configuration, data D and data /D read from a memory cell are transferred to a pair of data lines DB and /DB. A gate control circuit GC detects the transfer of the data D and /D to the pair of data lines DB and /DB, and activates a control signal CS. When the control signal CS is activated, transfer gates are both made conductive. The data D and /D are transferred to latch circuits. The latch circuits latches the data D and /D. Output data DO responsive to the latched data is output to an outside through a data input/output pin DQ from an output buffer circuit OB.

[Patent Document 1] JP Patent Kokai Publication No. JP-A-08-161883

### SUMMARY

The entire disclosure of the above patent document is incorporated herein by reference thereto. An analysis result below is given by present inventors.

### <Problem at a Time of Data Masking>

A write operation using a data mask function and a problem of the write operation will be described. The data mask function is a function in which, when the control signal data mask DM is specified, the write operation of external write data into the memory cell corresponding to I/O data specified by the data mask signal is not actually performed. The write operation of external write data into the memory cell corresponding to I/O data not specified by the data mask signal is actually performed. That is, in a same write cycle, there are a memory cell into which external write data associated with the memory cell is actually written and a memory cell into which external write data associated with the memory cell is not actually written. A related approach of implementing this function will be described with reference to a waveform diagram in FIG. 7 (which has been newly prepared by the inventor of the present invention and the like).

In the case of data masking, precharging of the MIO lines and the LIO lines is released, and the signal DIOWEB of the sub-amplifier (in the SWC circuit) in FIG. 4 is set to Low (as shown in FIG. 7A) to cause the pass gates 401 and 402 to turn on (conduct). The operation performed so far is the same as a normal write operation.

When data masking is specified (the data mask signal DM is High), a data write is not performed. Data masking can be specified, corresponding to a bit of write data. When data masking is specified for the main amplifier MA<k> 302 connected to the k-th pair of MIO lines of MIOT<k> and MIOB<k>, an output of the write amplifier of the main amplifier MA <k> 302 is brought into an off state (output disable state), and the MIO lines MIOT<k> and MIOB<k> that have been precharged/equalized are brought into the floating state. In this case, when data masking is not specified for the (k+1)th pair of MIO lines of MIOT<k+1> and MIOB<k+1> not shown, the write amplifier of the main amplifier MA<k+1> connected to the (k+1)th pair of MIO lines complementarily drives the (k+1)th pair of MIO lines of MIOT<k+1> and MIOB<k+1> (to different voltages, respectively), according to write data. That is, the (k+1)th pair of MIO lines of MIOT<k+1> and MIOB<k+1> assumes the mutually different voltages.

When the output of the write amplifier of the main amplifier MA<k> 302 in FIG. 3 is in the off state (output disable state), the signals DWAE0P and DWAE1P remain High, and the signals DWAE0N and DWAE1N remain Low, and the PMOS transistors 901 and 902 and the NMOS transistors 903 and 904 for A WRITE are all made non-conductive.

The pair of MIO lines and the pair of LIO lines connected to the pair of MIO lines via the SWC pass gates 401 and 402 (in FIG. 4) are kept in the floating state. When the column selection signal YS (on the YS line) goes High, the bit line BLT and the LIO line LIOT are connected, and the bit line BLB and the LIO line LIOB are connected (as shown in FIG. 7D). The YS line simultaneously connects a plurality of the pair of LIO lines and the pair of bit lines, and the data mask function is specified so that the data mask function functions for the specified specific pair of MIO lines, pair of LIO lines, and pair of bit lines (in the DDR2, DDR2 or the like, for example). Thus, it must be ensured that the column selection signal YS is set to High. That is, the YS line for the pair of bit lines in the specific pair of MIO lines, pair of LIO lines, and pair of bit lines to which data masking has been specified cannot be selectively set to Low. Then, by the YS line being driven to High, electric charge of the pair of LIO lines LIOT/B is discharged by the sense amplifier (SA) through the pair of bit lines BLT/B connected to the pair of LIO lines LIOT/B (as shown in FIG. 7C).

Further, in this case, the pair of MIO lines MIOT/B is also connected to the pair of LIO lines LIOT/B via the pass gates 401 and 402 (refer to FIG. 4) in the SWC circuit in a conduction state. Thus, electric charge of the pair of MIO lines MIOT/B is also discharged by the sense amplifier (SA) connected to the pair of LIO lines LIOT/B via the switches 501 and 502 (refer to FIG. 5) in a conductive state (as shown in FIG. 7B).

In this case, the electric charge on the pair of LIO lines LIOT/B are flown into the pair of bit lines BLT/B. Thus, a Low level of the pair of bit lines BLT/B is raised (refer to a “raised” broken line of the pair of bit lines BLT/B when the YS line is High in FIG. 7D). Referring to FIG. 7D, it is assumed that the pair of bit lines BLT/B is respectively kept High and Low before the pulse of the YS line rises to High level by the sense amplifier (SA) that amplifies data held in the memory cell that has been output to the pair of bit lines BLT/B.

As shown in FIG. 5, the sense amplifier (SA) is configured to receive the pair of bit lines BLT/BLB at the transistors cross-coupled. When the bit line BLB in FIG. 5 is raised from a Low level, for example, the gate-to-source voltage Vgs of the PMOS transistor 506 (a gate thereof is connected to the bit line BLB) that fixes the bit line BLT at High level is reduced, and the gate-to-source voltage Vgs of the NMOS transistor 504 (that has a gate connected to the bit line BLB) in a non-conduction state is increased. Then, the NMOS transistor 504 in the non-conduction state is made conductive, and electric charge is discharged from the bit line BLT to the power supply VSS through the NMOS transistor 504. The voltage of the bit line BLT is thereby reduced (refer to a “lowered” broken line of the pair of bit lines BLT/B when the YS line is High in FIG. 7D).

When the current driving capability of the sense amplifier (SA) is strong, this phenomenon does not pose a problem in particular. However, when the current driving capability of the sense amplifier (SA) is comparatively weak, an amount of rising of the Low level of the bit line BLB and an amount of lowering of the High level of the bit line BLT are more increased.

Further, when an operating point of the sense amplifier (SA) has a bias due to a manufacturing variation or the like, the voltage of the bit line BLT at the High level and the voltage of the bit line BLB at the Low level are finally reversed. When the YS line is High in the voltage waveforms of the pair of bit lines BLT/B in FIG. 7D, for example, the “raised” voltage that rises from the Low level crosses the “lowered” voltage that falls from the precharge voltage, and then the high/low relationship of the voltages of the pair of bit lines BLT/B is reversed.

The sense amplifier (SA) originally includes a function of amplifying a difference in voltage-level between the pair of bit lines BLT/B. Thus, when the sense amplifier (SA) differentially amplifies this reversed voltage ΔV, inverted data is written to the memory cell. Thus, the memory cell data will be broken (which will lead to collapse of user data). In recent years, as the fine fabrication process is developed, this phenomenon is noticeably observed. Reduction in yields is thereby brought about.

It is desired that the sense amplifier be arranged with a layout pitch of the bit line connected to the memory cell having a smallest layout pitch. As a result, a current driving capability of one sense amplifier is losing capability of driving the data buses (MIOT, MIOB) arranged at a top of the hierarchy. In other words, a value of the ratio between the current driving capability of the sense amplifier and the total capacitance value of a load which can be driven by the sense amplifier on a load model without malfunction has become small. On the other hand, the load capacitance value of each of the data buses (MIOT, MIOB) on the top of the hierarchy that performs input/output with the outside of the memory array, being most distant from the memory cell due to the hierarchical data bus configuration has increased because of an increase in the area of the memory cell array (increase in the number of memory cells). In this application, it is important that the sense amplifier having the value of the ratio be not connected to the data buses (MIOT, MIOB) on the top hierarchy among hierarchy data buses to which write masking has been specified at a time of a write operation. Further, since such a connection control is performed in the memory array, it is important that the circuit size of a control circuit arranged in the memory array for the connection control be not increased.

In order to solve one or more of the above-mentioned problems, the invention may be summarized as follows, though not limited thereto. Bracketed symbols assigned to elements in the section of means for solution to the problem illustrate an example of a correspondence relationship with an exemplary embodiment that will be described later in order to just facilitate understanding of the present invention. Needless to say, the symbols should not be interpreted as limiting the range of the invention.

According to one aspect of the present invention, there is provided a semiconductor device comprising:

a pair of primary data lines (BLB/T, LIOT/B) having one or more memory cells connected thereto and transferring data bidirectionally;

a pair of secondary data lines (MIOT/B) transferring data bidirectionally;

a switch (401/402) controlling connection between the pair of primary data lines (BLB/T, LIOT/B) and the pair of secondary data lines (MIOT/B),

the pair of secondary data lines (MIOT/B) being connected via the switch (401/402) to the pair of primary data lines (BLB/T, LIOT/B) to output internal data information held by the memory cell to an outside, the pair of secondary data lines (MIOT/B) receiving external data information from the outside;

a primary amplifier (SA in FIG. 3, SA in FIG. 13) connected to the pair of primary data lines, the primary amplifier amplifying and holding the data information on the pair of primary data lines;

a secondary amplifier (MA in FIG. 3, write amplifier in FIG. 13) connected to the pair of secondary data lines; and

a switch control circuit (FIG. 10, 801 in FIG. 13) that control the switch pair. In the present invention, when writing data, the secondary amplifier drives the pair of secondary data lines (MIOT/B), in accordance with the external data information. The data information on the pair of secondary data lines is transferred to the pair of primary data lines via the switch in a conduction state, and the internal data information held by the primary amplifier is rewritten by the external data information. As one of features of the present invention, the switch control circuit performs control so as to make the switch (401, 402) conductive when two data lines constituting the pair of secondary data lines (MIOT/B) assume voltages different in logic level from each other, and to make the switch (401, 402) non-conductive when the two data lines constituting the pair of secondary data lines (MIOT/B) assume a same predetermined voltage.

According to another aspect of the present invention, there is provided a semiconductor device comprising: a complementary first pair of data lines (BLT, BLB), a complementary second pair of data lines (LIOT, LIOB), and a complementary third pair of data lines (MIOT, MIOB) in each of which one signal is represented by complementary signals; a first amplifier (SA) connected to the first pair of data lines; a first switch (501, 502 in FIGS. 5 and 13) that controls connection between the first pair of data lines and the second pair of data lines; a second switch (SWC: 401, 402 in FIG. 10) that controls connection between the second pair of data lines and the third pair of data lines; a second amplifier (406, 407, 403, 404, 405 in FIG. 10) that amplifies data on the second pair of data lines to output the amplified data to the third pair of data lines; a third amplifier (901 to 904 in FIG. 8) connected to the third pair of data lines; and a control circuit (logic circuit 801 in FIGS. 12 and 13) that controls the second switch. As a feature of the present invention, the control circuit controls the second switch to be turned off when two data lines constituting the third pair of data lines are both in a first state, the second switch controls the second pair of data lines and the third pair of data lines to be disconnected, and output data of the first amplifier is output to the second pair of data lines via the first switch. When the two data lines constituting the third pair of data lines are both in a second state different from the first state according to data output by the third amplifier, the control circuit controls the second switch to be turned on, thereby controlling the second pair of data lines and the third pair of data lines to be connected. The first amplifier then receives the data output by the third amplifier.

According to the present invention, when write masking is specified, the first pair of data lines in a floating state is disconnected from the second pair of data lines. Breakdown of data held in a memory cell on the third pair of data lines connected to the second pair of data lines is thereby avoided.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing an example of a configuration of a semiconductor memory device to which the present invention is applied;

FIG. 2 is a diagram showing an example of a configuration of a sense amplifier to which the present invention is applied;

FIG. 3 is a diagram showing an example of a configuration of hierarchical I/O lines to which the present invention is applied;

FIG. 4 is a diagram showing an example of an SWC configuration (in a related art);

FIG. 5 is a diagram showing an example of a configuration of a sense amplifier to which the present invention is applied;

FIGS. 6A to 6D are diagrams showing an example of a write operation in the related art;

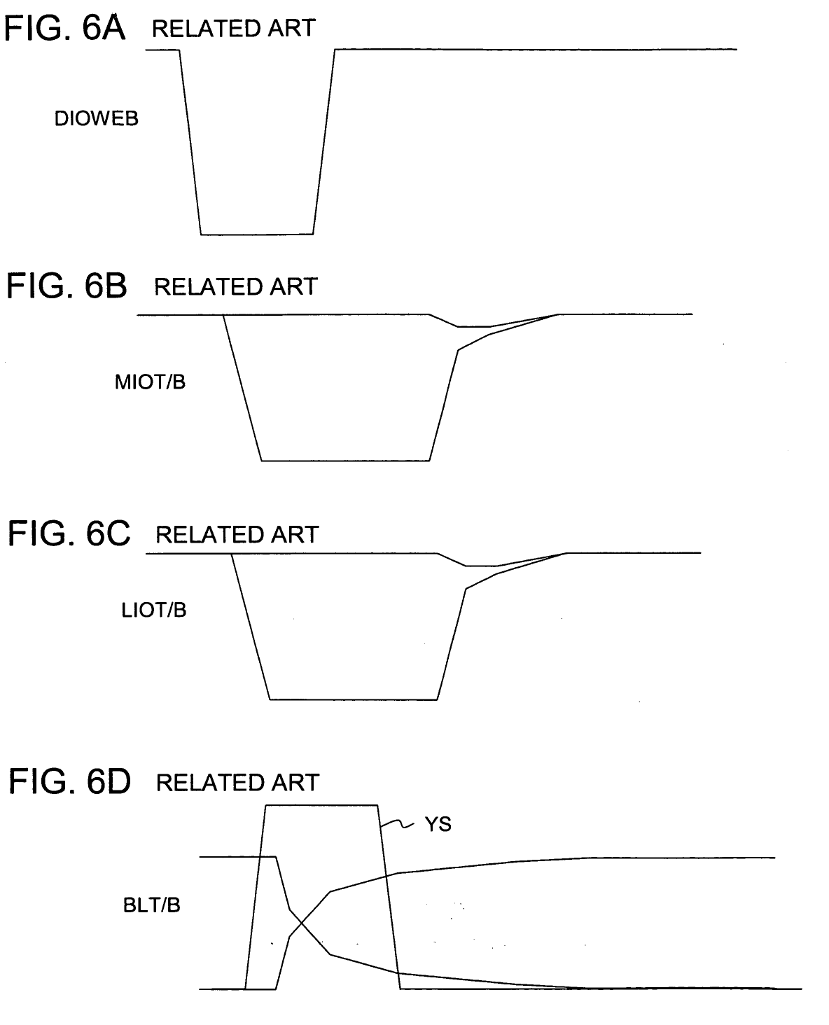

FIGS. 7A to 7D are diagrams showing an example of an operation at a time of data masking in the related art;

FIG. 8 is a diagram showing an example of a configuration of a main amplifier to which the present invention is applied;

FIG. 9 is a diagram showing an example of a configuration of a write circuit in a hierarchical I/O system in a related art;

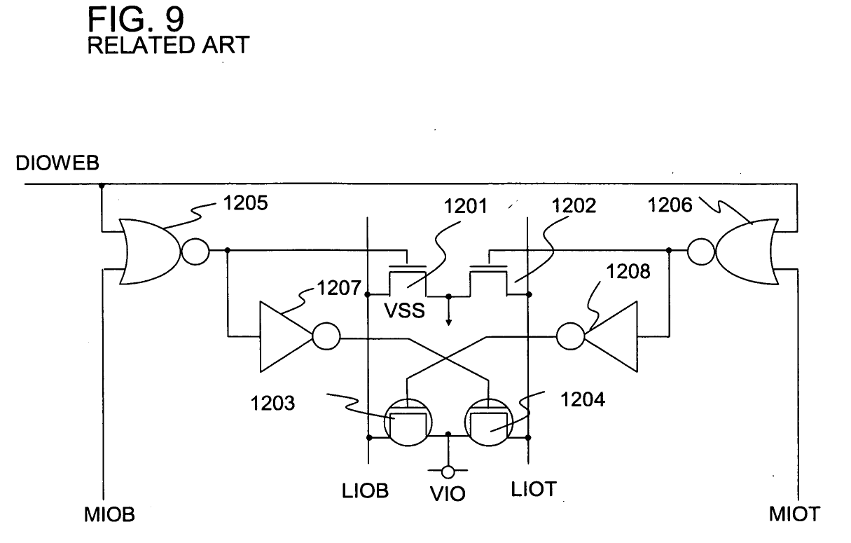

FIG. 10 is a diagram showing an SWC configuration in an exemplary embodiment of the present invention;

FIGS. 11A to 11D are diagrams showing an example of an operation at a time of data masking in the exemplary embodiment of the present invention;

FIG. 12 is a diagram showing an SWC configuration in another exemplary embodiment of the present invention;

FIG. 13 is a diagram schematically showing a configuration of a main portion of the present invention; and

FIG. 14 is a diagram showing an example of a configuration of a logic circuit in the exemplary embodiment of the present invention.

### PREFERRED MODES

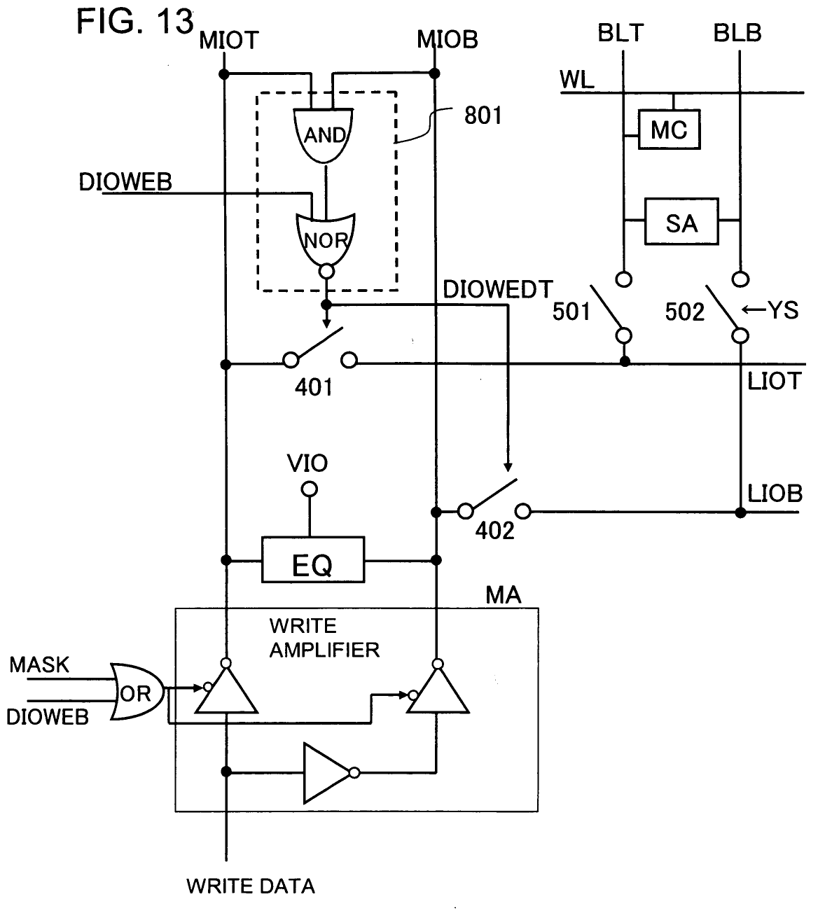

Preferred modes of the present invention will be described. FIG. 13 is a diagram schematically showing a configuration of a main portion of a semiconductor device according to one of the preferred modes of the present invention. Referring to FIG. 13, the semiconductor device according to the present invention includes a pair of data lines (MIOT, MIOB) of a first hierarchy through which complementary data is bidirectionally transferred, a pair of data lines (LIOT, LIOB) of a second hierarchy wherein the complementary data is bidirectionally transferred between the pair of data lines (MIOT, MIOB) of the first hierarchy and the pair of data lines (LIOT, LIOB) of the second hierarchy, and a switch pair (pass gates 401 and 402) that control connection between the pair of data lines (MIOT, MIOB) of the first hierarchy and the pair of data lines (LIOT, LIOB) of the second hierarchy.

When the complementary data is written from the pair of data lines (MIOT, MIOB) of the first hierarchy to the pair of data lines (LIOT, LIOB) of the second hierarchy, a main amplifier (write amplifier) of the first hierarchy connected to the pair of data lines (MIOT, MIOB) of the first hierarchy complementarily drives the pair of data lines (MIOT, MIOB) of the first hierarchy, responsive to write data supplied thereto from an outside. The complementary data is then transferred to the pair of data lines (LIOT, LIOB) of the second hierarchy via the switch pair (401, 402) that has been set to a conduction state.

In the present invention, when data is written from the pair of data lines (MIOT, MIOB) of the first hierarchy to the pair of data lines (LIOT, LIOB) of the second hierarchy, the main amplifier (write amplifier) of the first hierarchy connected to the pair of data lines (MIOT, MIOB) of the first hierarchy to which write masking has been specified is set to an off state. Write masking is hereinafter defined to prohibit actual writing of data to a corresponding memory cell, and has a same meaning as the above-mentioned data masking. Further, the main amplifier includes a read amplifier not shown that amplifies information on the pair of data lines (MIOT, MIOB) of the first hierarchy at a time of a read operation.

In the present invention, a switch control circuit (logic circuit: 801) is provided. The switch control circuit performs control so that the switch pair (401, 402) that controls connection between the pair of data lines (MIOT, MIOB) of the first hierarchy and the pair of data lines of the second hierarchy is brought into the non-conduction state using that the pair of data lines (MIOT, MIOB) of the first hierarchy targeted for write masking both assume an initialized potential (precharge voltage), thereby disconnecting the first pair of data lines (MIOT, MIOB) of the first hierarchy targeted for write masking and the pair of data lines (LIOT, LIOB) of the second hierarchy.

When the pair of data lines (MIOT, MIOB) of the first hierarchy has both the initialized potential (precharge voltage), an output of an AND circuit that constitutes the switch control circuit (801) goes High. An output of a NOR circuit (signal DIOWEDT) goes Low, irrespective of the value of a write mode signal (DIOWEB), and the switch pair (401, 402) is brought into a non-conduction state. Two switches of the switch pair (401, 402) are controlled in common to be made conductive or non-conductive by an output of the switch control circuit (801). When the signal DIOWEB is set to have an inverted logic level, a NAND circuit can be substituted for the AND circuit, and an AND circuit can be substituted for the NOR circuit.

In the present invention, the pair of data lines (LIOT, LIOB) of the second hierarchy is connected via a switch pair (501, 520) to an amplifier (sense amplifier SA) which is connected to a pair of data lines (pair of bit lines BLT, BLB). The pair of data lines (pair of bit lines BLT, BLB) is connected to a memory cell (MC) capable of being written and read. The conduction(on)/non-conduction (off) of two switches of the switch pair (501, 502) is commonly controlled by a selection signal (column selection signal YS) that controls column selection/non-selection of the pair of data lines (BLT, BLB).

In the present invention, at a time of write masking, electric charge of one of two data buses (LIOT, LIOB) that constitute the pair of data lines (LIOT, LIOB) of the second hierarchy is discharged by the amplifier (SA) connected via the switch pair (501, 502) to the pair of data lines (LIOT, LIOB) of the second hierarchy. Information indicated by the pair of data lines of the second hierarchy at this point is immediately preceding information (data in the memory cell in which the information has been refreshed) in the corresponding memory cell into which writing has not been performed. In this case, the pair of data lines (LIOT, LIOB) of the second hierarchy is set to be disconnected from the pair of data lines (MIOT, MIOB) of the first hierarchy by the switch pair (401, 402) which is set in the non-conduction state.

In the write operation, the write mode signal (DIOWEB) is made active (Low), and the main amplifier (write amplifier) of the first hierarchy complementarily drives the pair of data lines (MIOT, MIOB) of the first hierarchy, in response to write data (Write data) from the outside. As a result, one of the data lines MIOT and MIOB goes High, and the other of the data lines MIOT and MIOB goes Low. Then, the output of the AND circuit of the switch control circuit (801) goes Low. In this case, the output (DIOWEDT) of the NOR circuit that receives the Low output of the AND circuit and the write mode signal (DIOWEB) at the Low level goes High, thereby turning on (conducting) both of the switch pair (401, 402). The pair of data lines (MIOT, MIOB) of the first hierarchy and the pair of data lines (LIOT, LIOB) of the second hierarchy are set to a conduction state. The pair of data lines (BLT, BLB) is connected to the pair of data lines (LIOT, LIOB) of the second hierarchy via the switch pair (501, 502) which is set to the conduction state by the selection signal (YS). As a result, the complementary data transferred from the pair of data lines (MIOT, MIOB) of the first hierarchy to the pair of data lines (LIOT, LIOB) of the second hierarchy is supplied to the amplifier (SA) via the switch pair (501, 502) and is then amplified. Then, the data is written to the memory cell (MC).

It needs to be noted that, at a time of one write cycle, a first data bus system (constituted from the pair of data lines of the first hierarchy, pair of data lines of the second hierarchy, and pair of data lines (BLT, BLB) on the third hierarchy) for which the write masking is performed and a second data bus system for which the write masking is performed are present, and that each of the switch pairs of the first and second data bus systems is operated by control of the corresponding switch control circuit.

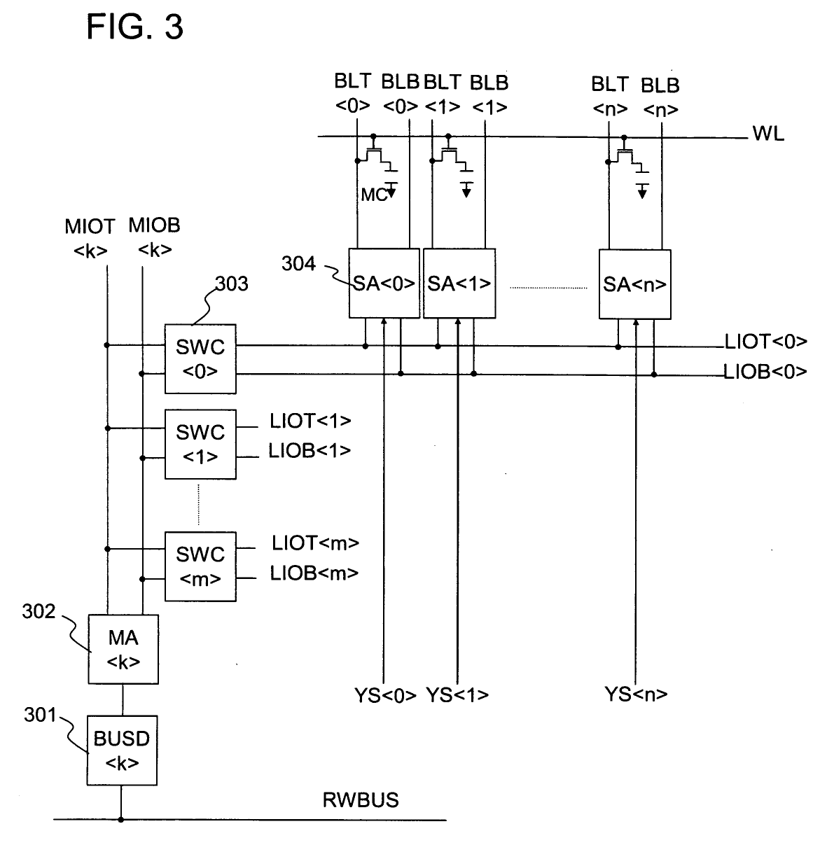

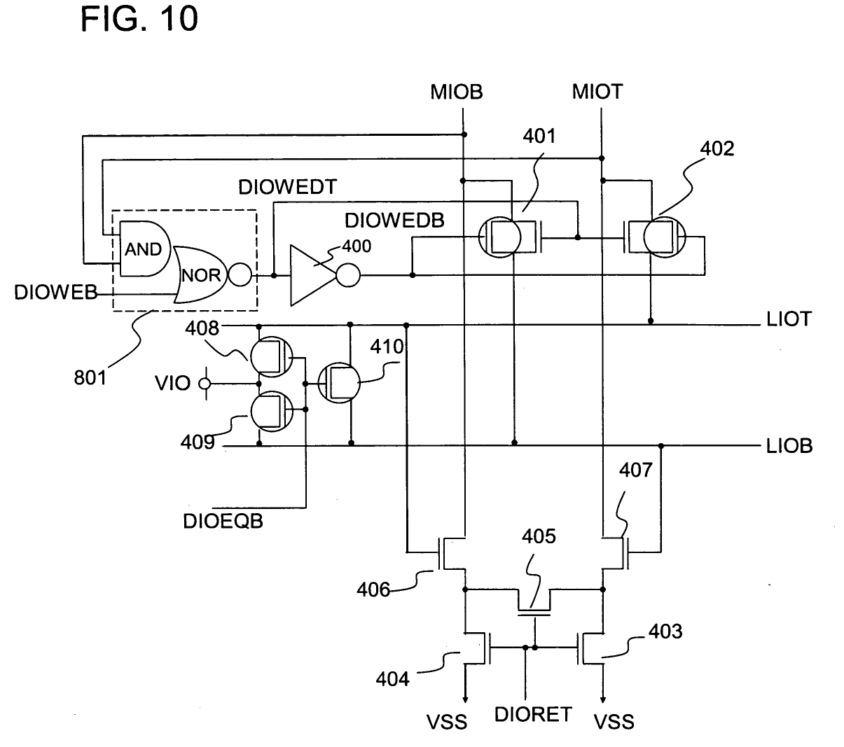

In the read operation from a memory cell, data transfer in an opposite direction, that is, data transfer (read) from the pair of data lines (LIOT, LIOB) of the second hierarchy to the pair of data lines (MIOT, MIOB) of the first hierarchy is performed by driving the pair of data lines (MIOT, MIOB) of the first hierarchy by a sub-amplifier (formed of transistors 406, 407, 403, 404, and 405 in FIG. 10) that receives complementary signals on the pair of data lines (LIOT, LIOB) of the second hierarchy. More specifically, the data in the memory cell (MC) read onto the pair of data lines (BLT, BLB) is amplified and held by the amplifier (SA), and is transferred to the pair of data lines (LIOT, LIOB) of the second hierarchy via the switch pair (501, 502) which is set to the conduction state by the selection signal (YS). When the data is read from the pair of data lines (LIOT, LIOB) of the second hierarchy to the pair of data lines (MIOT, MIOB) of the first hierarchy, the switch pair (401, 402) is set to the non-conduction state by the switch control circuit (801). It is because the write mode signal (DIOWEB) is inactive. Further, the output of the write amplifier in the main amplifier of the first hierarchy is set to an off state (high-impedance state). The complementary data (data read from the memory cell) transferred on the pair of data lines (LIOT, LIOB) of the second hierarchy is output to the pair of data lines (MIOT, MIOB) of the first hierarchy by the sub-amplifier. Then the data is amplified by the read amplifier included in the main amplifier (MA302 in FIG. 3) on the pair of data lines (MIOT, MIOB) of the first hierarchy, and is output to a data transfer bus (RWBUS in FIG. 3).

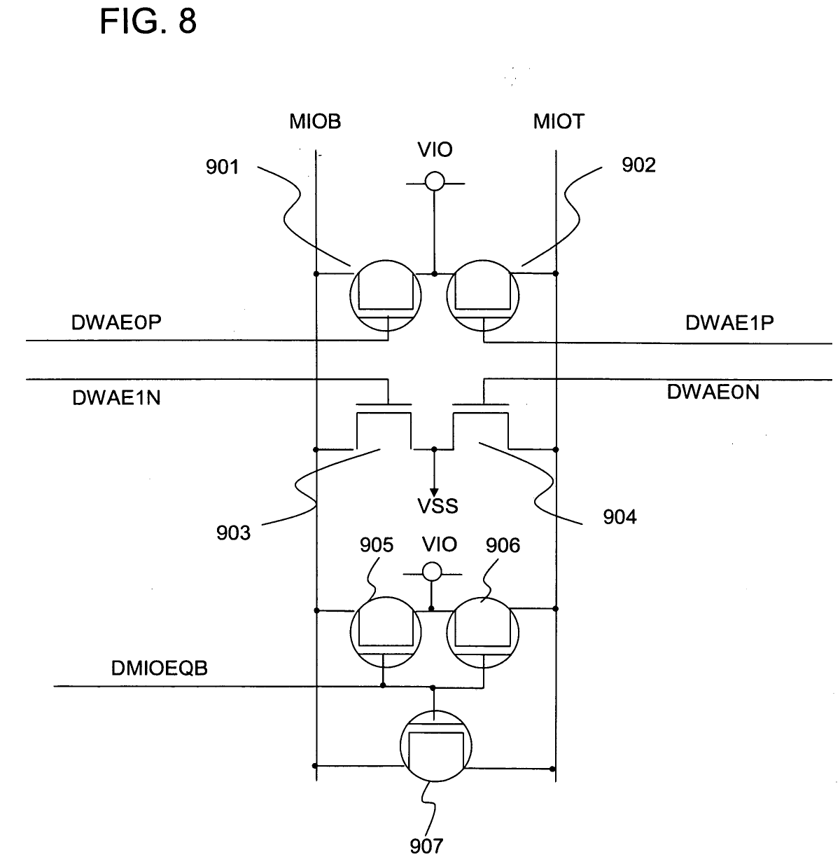

In the present invention, there is provided a circuit (designated by reference symbol EQ in FIG. 13, specifically transistors 905, 906, 907 in FIG. 8) that sets the pair of data lines (MIOT, MIOB) of the first hierarchy to the initialized potential, and equalizes potentials of the pair of data lines of the first hierarchy. When data is written, the pair of data lines (MIOT, MIOB) of the first hierarchy is set to the initialized potential before the main amplifier (write amplifier) is operated.

In the present invention, a parasitic capacitance of the pair of data lines (MIOT, MIOB) of the first hierarchy is larger than a parasitic capacitance of the pair of data lines (LIOT, LIOB) of the second hierarchy.

In the present invention, a. driving capability (current driving capability) of the main amplifier (write amplifier formed of transistors 901 to 904 in FIG. 8) of the first hierarchy is larger than a driving capability (current driving capability) of the sub-amplifier (composed by the transistors 406, 408 in FIG. 10) that receives the pair of data lines of the second hierarchy and drives the pair of data lines of the first hierarchy.

When a mask signal (MASK) that controls write masking is activated in the present invention, the main amplifier (write amplifier) of the first hierarchy is brought into the off state (output disable state) indicating the high-impedance state, irrespective of the value of the write mode signal (DIOWEB). A switch not shown that disconnects an output terminal of the write amplifier from the pair of data lines of the first hierarchy may be applied in place of the mask signal.

The write amplifier of the main amplifier of the first hierarchy in an output enable state complementarily drives the MIO lines MIOT and MIOB based on received write data. An output of the write amplifier in the output disable state is brought into the off state (high-impedance state). Though no particular limitation is imposed, in the example schematically shown in FIG. 13, the write amplifier of the first hierarchy is formed as an inverting amplifier (tri-state inverter) for which output enabling/disabling is controlled by a signal (output of the OR circuit) that controls output enabling. When the write mode signal (DIOWEB) is inactive (High), the output of the OR circuit is set to High, and the write amplifier is brought into the output disable state (output off state). When a read is performed, the write mode signal (DIOWEB) is made inactive (High), the output of the OR circuit is set to High, and the write amplifier is brought into the output disable state (output off state). When the write mode signal (DIOWEB) is active (such as a Low state) and the write mask signal (MASK) is inactive (Low), the output of the OR circuit is set to Low, the write amplifier is brought into the output enable state, and drives two data lines (MIOT, MIOB) that constitute the pair of data lines of the first hierarchy to different voltages, corresponding to external write data (write data). When a write operation is performed, a plurality of the write mask signals (MASK) supplied from the outside are set, corresponding to the first and second data bus systems, and perform control whether or not to transfer Write data (bit data) to be supplied to each data bus system to the corresponding pair of data lines (MIOT/B) of the first hierarchy.

As described above, when write masking is performed in the present invention, it is noted that the pair of data lines (MIOT, MIOB) of the first hierarchy is in a floating state initialized to a High level (VIO voltage). When the pair of data lines (MIOT, MIOB) of the first hierarchy has both the initialized voltage (High level), the switch pair (401, 402) is brought into the non-conduction state, thereby limiting electric charge to be discharged by the sense amplifier (SA) to those of the pair of data lines (LIOT, LIOB) of the second hierarchy. With this arrangement, a raised/lowered amount of each of the pair of data lines (BLT, BLTB) at a time of the write masking is reduced, the reversal of High and Low levels of the pair of data lines (BLT, BLTB) due to the sense amplifier (SA), in response to the raised Low level and the lowered High level of the pair of data lines (LIOT, LIOB) is caused not to occur. As a result, when the memory cell (MC) connected to the pair of data lines (BLT, BLTB) is selected (during a period in which the connected word line is High), the pair of data lines (BLT, BLTB) and the pair of data lines (LIOT, LIOB) of the second hierarchy are kept at a value (of refreshed data) held in the memory cell (MC), thereby avoiding rewriting of the memory cell (MC) by inverted data of the held data. Assume that write masking is carried out in a configuration having the sense amplifier (SA) with a small current driving capability due to development of a fine fabrication process and voltage reduction. Even so, break down of data in the memory cell (MC) can be avoided for the memory cell (MC) corresponding to the data bus system on the hierarchy for which the write masking is performed. Data security can be ensured, and reliability can be improved.

When write masking is performed, control of making the switch pair (401, 402) non-conductive can also be performed by using the write mask signal (MASK in FIG. 13). However, by employing the configuration in which the switch pair (401, 402) is brought into the non-conduction state by using that the pair of data lines (MIOT, MIOB) of the first hierarchy is kept at an initialized voltage, the need for an interconnect space for the write mask signal (MASK) is eliminated to achieve area saving. A description will be given below in connection with exemplary embodiments.

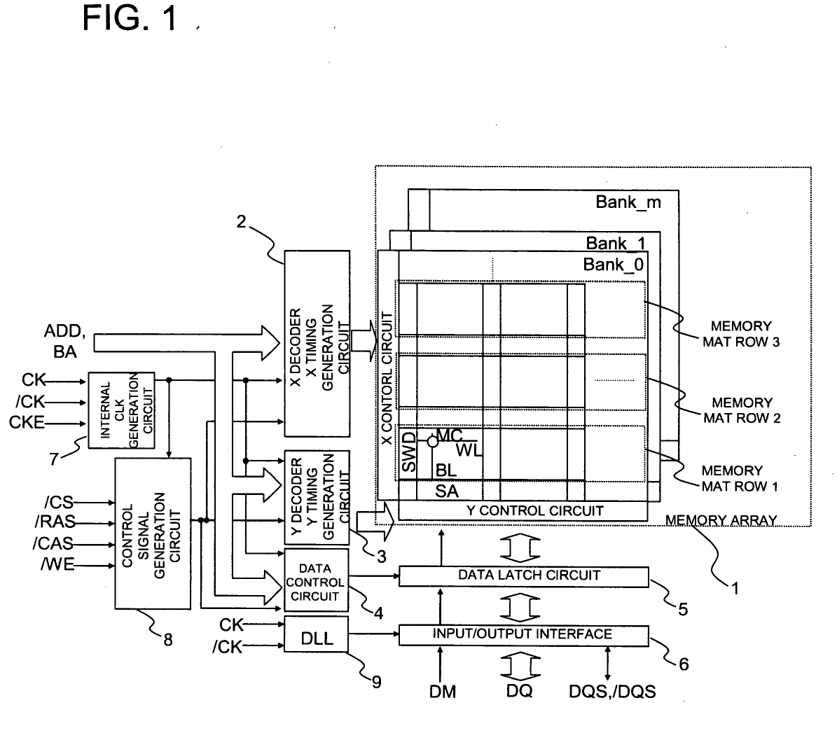

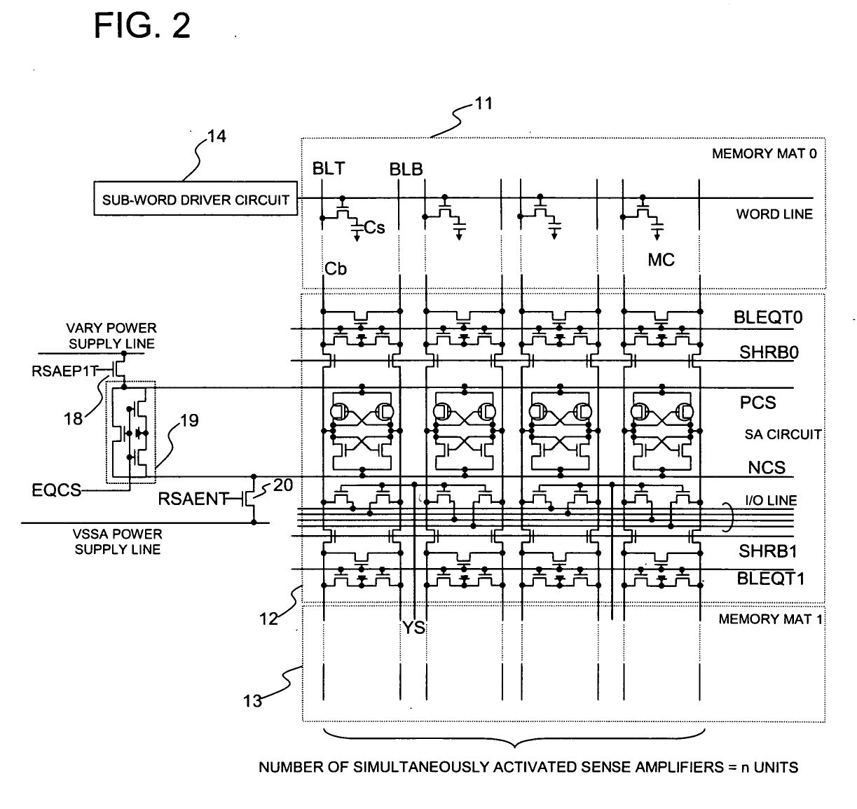

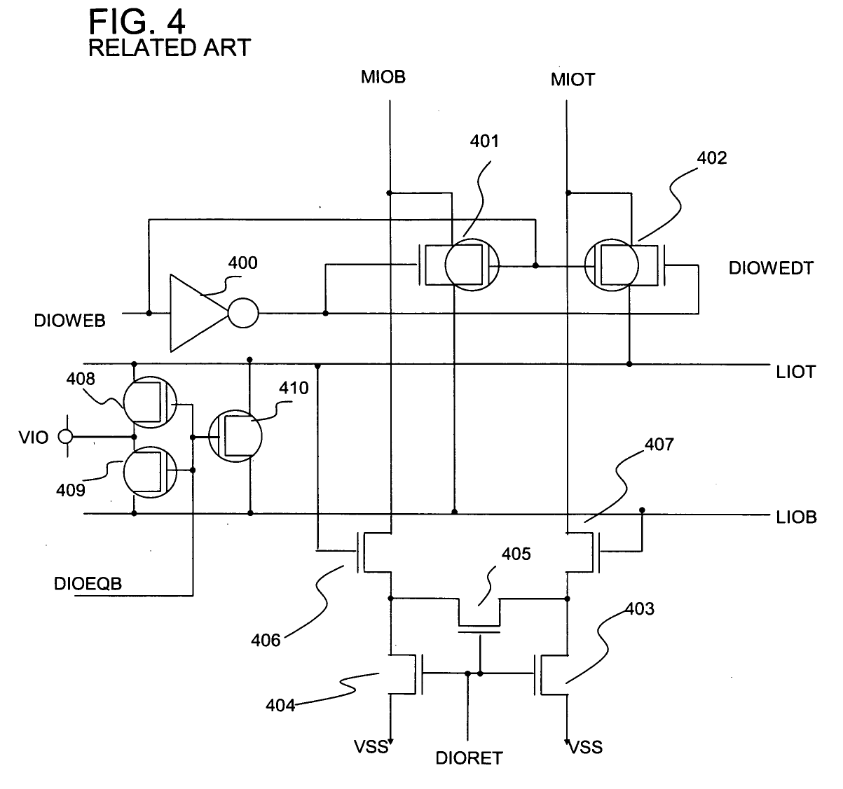

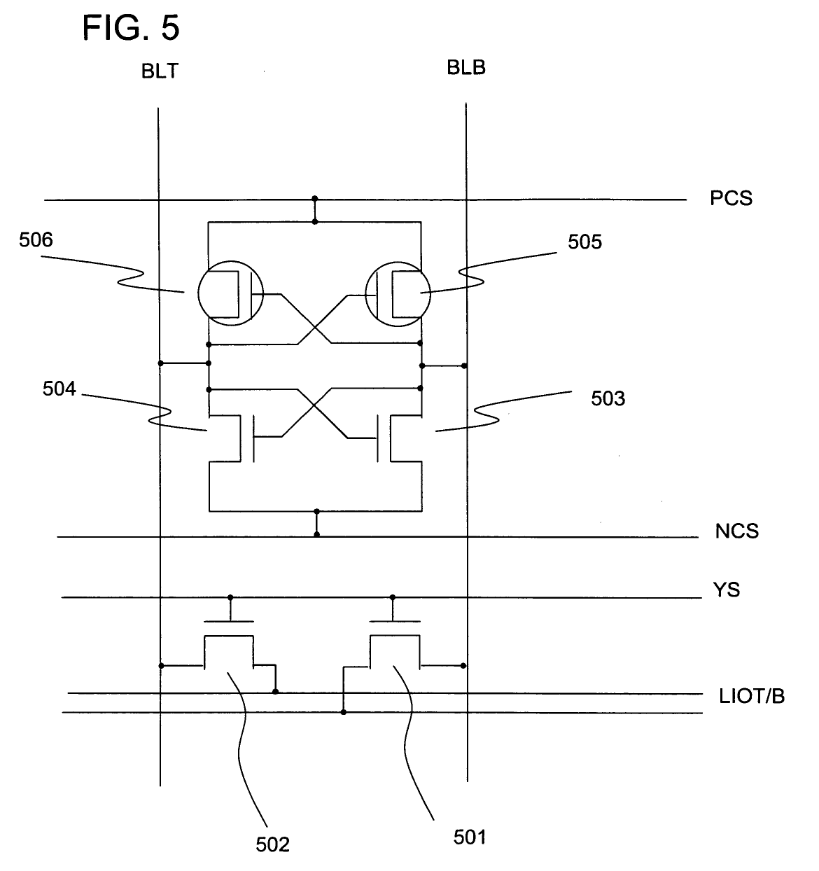

In the following exemplary embodiments, a semiconductor device has an overall configuration of a semiconductor device shown in FIG. 1. A sense amplifier (SA) in FIG. 1 has the configuration shown in FIG. 2, and a hierarchical I/O configuration of MIO and LIO lines has the configuration shown in FIG. 3. Further, a write amplifier of a main amplifier (MA) <k> 302 in FIG. 3 has the configuration shown in FIG. 8, and a sense amplifier (SA<i> 304 (i=0 to n) has the configuration shown in FIG. 5. In the exemplary embodiment of the present invention, the configuration of SWC<j> 303 (j=0 to m) in FIG. 3 is different from the configuration in FIG. 4. A difference between the embodiment of the present invention and the related art described above will be mainly described, and a description of the same components as those in the related art will be omitted as necessary in order to avoid repetition.

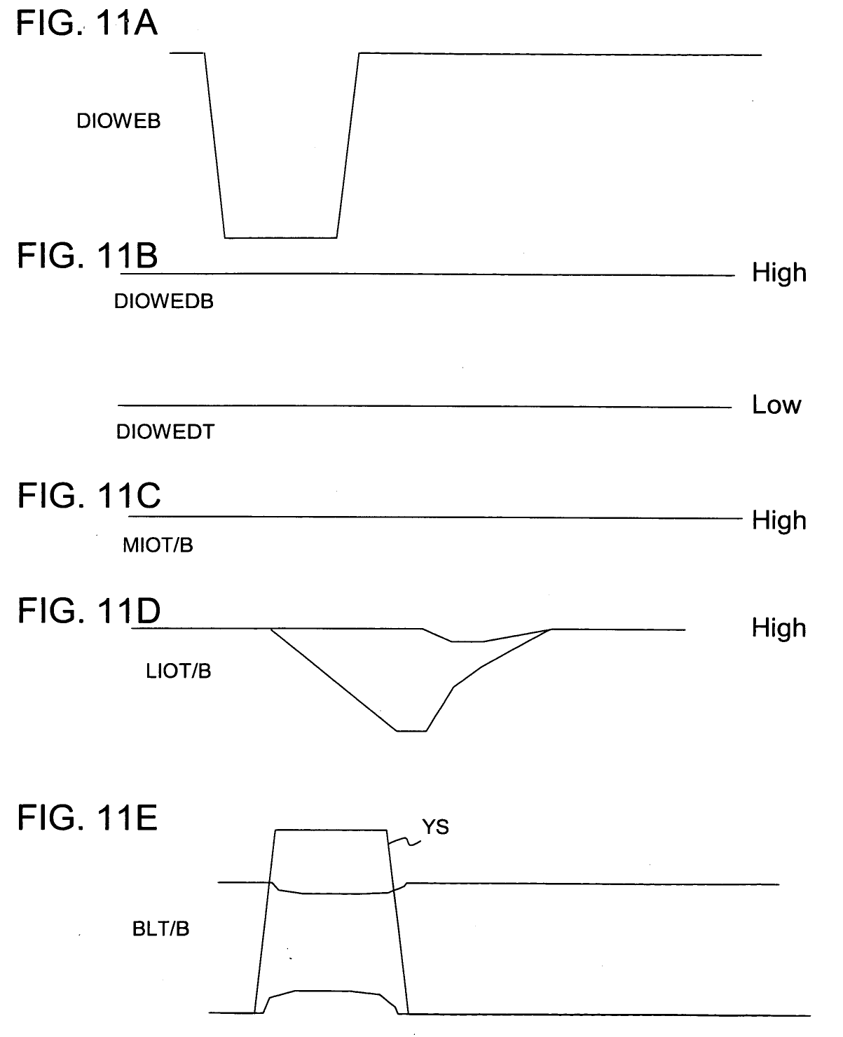

FIG. 10 is a diagram showing an SWC configuration in a first exemplary embodiment of the present invention. Referring to FIG. 10, in this embodiment, a logic circuit 801 is further provided in the configuration shown in FIG. 4. The logic circuit 801 includes an AND circuit that receives MIO lines MIOT and MIOB and a NOR circuit that receives an output of the AND circuit and a signal DIOWEB (Data I/O Write Enable Bar). An output of the NOR circuit is connected to gate terminals of NMOS transistors of pass gates 401 and 402. An inverted signal of the output of the NOR circuit is connected to gate terminals of PMOS transistors of pass gates 401 and 402. FIG. 11 is a timing waveform diagram explaining an operation of the circuit in FIG. 10.

Two inputs of the AND circuit of the logic circuit 801 are connected to the MIO lines MIOT and MIOB. The NOR circuit receives the output of the AND circuit and the write mode signal DIOWEB that is active Low, and outputs a negative logic sum of these output of the AND circuit and the write mode signal DIOWEB, as a pass gate activation signal DIOWEDT. Then, the signal DIOWEDT and an inverted signal DIOWEDB of the signal DIOWEDT are supplied to the gates of the NMOS transistor and the PMOS transistor of the pass gates 401 and 402. In other words, the logic circuit 801 performs a logical operation of the write mode signal DIOWEB and the pair of MIO lines, thereby controlling opening or closing of the pass gates 401 and 402.

The MIO lines MIOT and MIOB are precharged to a voltage VIO by PMOS transistors 905, 906, and 907 in FIG. 8 when the semiconductor device is not operated.

When a normal operation without using data masking is performed, the MIOT line MIOT or MIOB transitions to Low due to write data. Thus, when the write mode signal DIOWEB is activated (set to Low), the signal DIOWEDT goes High. The pass gates 401 and 402 are made conductive (open), the MIO line MIOB and an LIO line LIOB are electrically connected, and the MIO line MIOT and an LIO line LIOT are electrically connected. With this arrangement, the LIO line connected to the MIO line that has transitioned to Low is discharged to a Low level, and a normal write operation is performed.

On the other hand, when data masking is specified, the pair of MIO lines MIOT/B is precharged and equalized to High. Thus, none of the MIO lines MIOT and MIOB transition to Low. Accordingly, in the circuit shown in FIG. 10, even if the write mode signal DIOWEB transitions to an active state (Low), the signal DIOWEDT is Low, and the signal DIOWEDB is high (as shown in FIG. 11B). The PMOS transistor and the NMOS transistor in the pass gates 401 and 402 are in the non-conduction state. Accordingly, when the data masking is performed, electric charge of the pair of LIO lines LIOT/B is discharged by the sense amplifier (SA) (as shown in FIG. 11D). That is, when the data making is performed, the MIOT and MIOB lines remain at a High level (as shown in FIG. 11C). The pass gates 401 and 402 are non-conductive, and electric charge of the pair of MIO lines MIOT/B are not transferred to the pair of LIO lines LIOT/B.

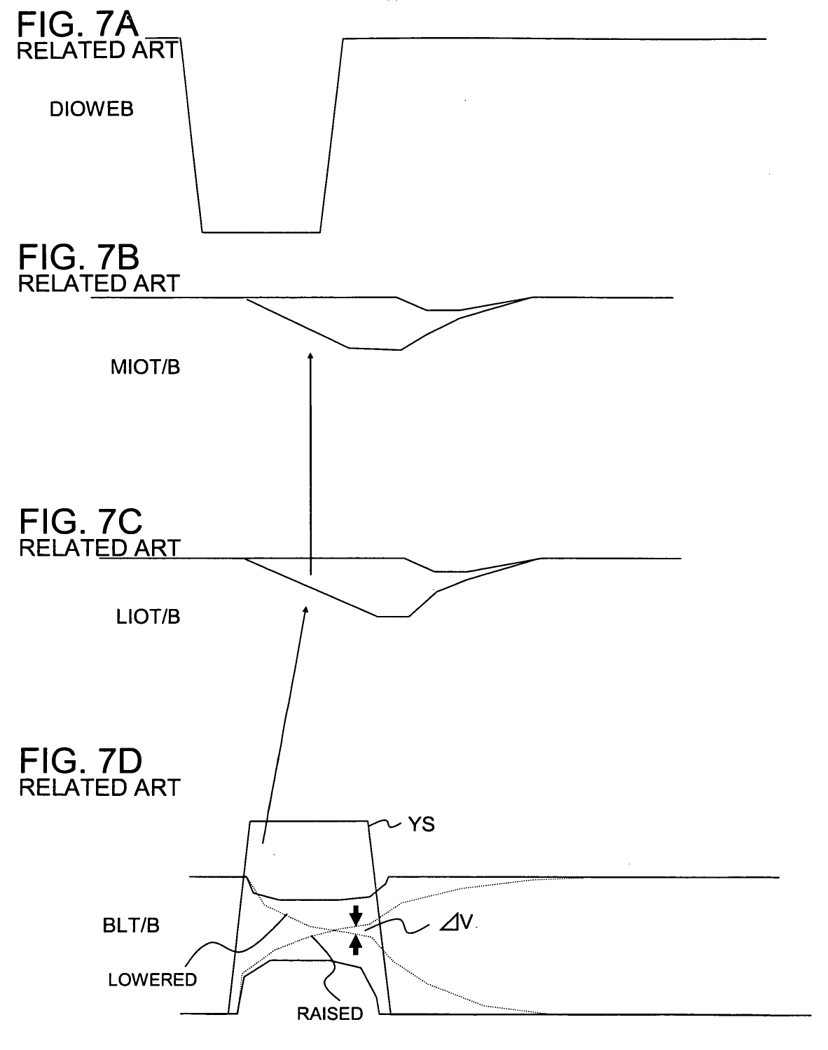

The sense amplifier (SA) for the pair of bit lines BLT/B of a column for which a YS line is High discharges electric charge of the pair of LIO lines LIOT/B via switches 501 and 502 (refer to FIG. 5) which are set to a conduction state by the High YS line (as shown in FIG. 7D).

When the YS line is High as shown in FIG. 7D, the LIO line LIOT/B corresponding to a Low level of the pair of bit lines BLT/B is discharged by the sense amplifier (SA), and approaches to a voltage that is the same as the voltage (Low level) of the pair of bit lines BLT/B. Electric charge of the pair of MIO lines MIOT/B is not transferred to the pair of LIO lines LIOT/B. Further, the pair of LIO lines LIOT/B have a parasitic capacitance smaller than that of the pair of MIO lines MIOT/B. Thus, an amount of electric charge of the pair of LIO lines LIOT/B is smaller than that of the pair of MIO lines MIOT/B. For this reason, it is enough to discharge the far smaller amount of electric charge by the sense amplifier (SA) than in a case where the pair of LIO lines LIOT/B and the pair of MIO lines MIOT/B are connected. Accordingly, even if the sense amplifier (SA) has a small current driving capability, the rising in the voltage of the Low level and the falling in the voltage of the High level of the bit line BLT/B when the YS line is High is reduced (as shown in FIG. 11E).

That is, at a time of a data write (when the signal DIOWEB in FIG. 11A is Low) and data masking is specified, falling from a High voltage and rising from a Low voltage of the pair of bit lines BLT/B connected to the pair of LIO lines LIOT/B via the switches 501 and 502 that have been made conductive according to a High pulse of the YS line (in FIG. 11E) is smaller than those in FIG. 7D. When the YS line goes Low and the switches 501 and 502 are both made non-conductive, the voltages of the pair of bit lines BLT/B are returned to those before the High pulse of the YS line due to an amplifying operation of the sense amplifier (SA). According to this embodiment, the collapse of data held in a memory cell at a time of data masking can be prevented.

The data masking function needs to be controlled for each MIO line. In this example, the pair of LIO lines can be driven by the write amplifier (formed of transistors 901 to 904 in FIG. 8) arranged in the main amplifier 302 in FIG. 3.

In this embodiment, the logic circuit (complex gate) 801 formed of the AND circuit and the NOR circuit is just added to the configuration in FIG. 4. It is enough to add MOS transistors (three PMOS transistors and three NMOS transistors) constituting the logic circuit 801 and having a small size necessary for driving the pass gates 401 and 402.

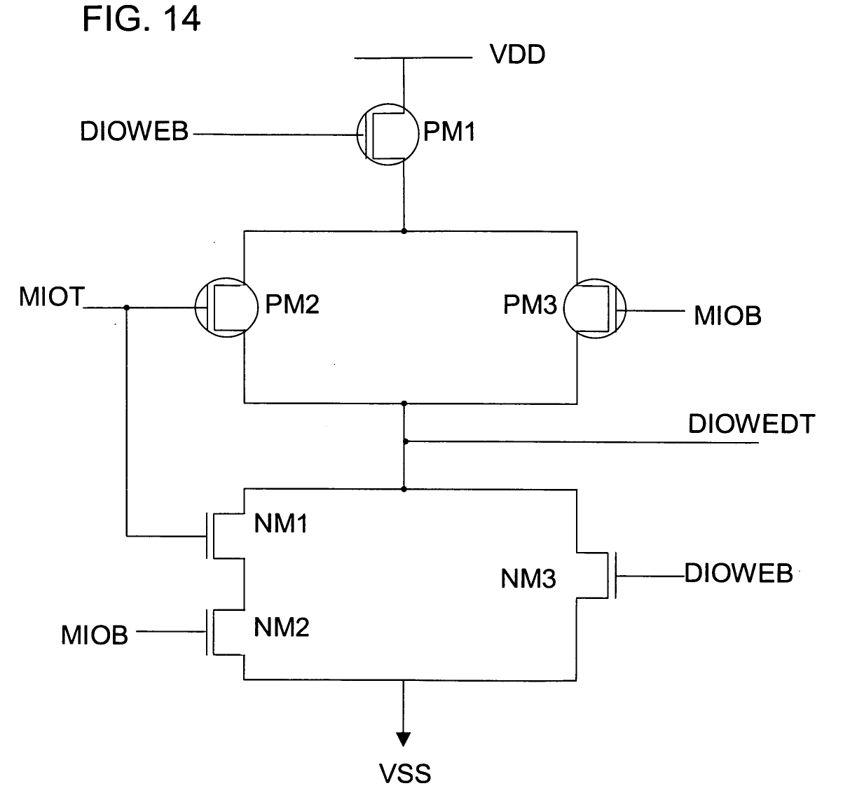

FIG. 14 shows an example of a configuration of the logic circuit 801. The logic circuit 801 includes a PMOS transistor PM1 that receives the signal DIOWEB at a gate thereof and a parallel circuit of two PMOS transistors PM2 and PM3 that receive the MIO lines MIOT and MIOB. PM1 and the parallel circuit of PM2 PM3 are connected in series between a high-potential power supply VDD and the signal DIOWEDT. The logic circuit 801 further includes an NMOS transistor NM3 that receives the signal DIOWEB at a gate thereof and a series circuit of two NMOS transistors NM1 and NM2 that receive the MIO lines MIOT and MIOB at gates thereof. NM3 and the series circuit of MN1 and MN2 are connected in parallel between the signal DIOWEDT and a low-potential side power supply VSS. The high-potential power supply VDD may assume a voltage that is the same as the precharge voltage VIO of the MIO lines.

When the MIO lines MIOT and MIOB both have a High level, the NMOS transistors NM1 and NM2 are made conductive, and the signal DIOWEDT goes Low. When the signal DIOWEB is High (write mode signal is inactive), the NMOS transistor NM3 is made conductive, and the signal DIOWEDT goes Low.

When the signal DIOWEB is Low (write mode signal is active), and at least one of the MIO lines MIOT and MIOB is Low, the PMOS transistor PM1 is made conductive, one of the PMOS transistors PM2 and PM3 is made conductive, and the signal DIOWEDT goes High.

The signal DIOWEDT and the signal DIOWEDB obtained by inverting the signal DIOWEDT by an inverter 400 (in FIG. 10) opens (turns on) or closes (turns off) the pass gates 401 and 402. Since it is enough to set the size of each of these MOS transistors to be small, the circuit size can be reduced, and the circuit can be accommodated in an SWC region. For this reason, there is also an advantage that an increase in the overall area of a chip can be prevented.

A write operation using the circuit in FIG. 10 will be described. When a data write is performed, the pair of MIO lines MIOT/B that has been precharged to the VIO voltage by the circuit composed by the transistors 905, 906, 907 in FIG. 8 before the write operation, is complementarily driven by the write amplifier composed by the transistors 901 to 904 in FIG. 8, according to write data. One of the MIO lines MIOT and MIOB is thereby set to High and the other of the MIO lines MIOT and MIOB is set to Low. As a result, the output of the AND circuit in the logic circuit 801 goes Low, and the output DIOWEDT of the NOR circuit that receives the Low write mode signal (DIOWEB) and the Low output of the AND circuit goes High. The signal DIOWEDB goes Low, thereby making the pass gates 401 and 402 conductive. That is, when the write mode signal (DIOWEB) is active (Low) and except when values of the MIO lines MIOT and MIOB are both High, the pass gates 401 and 402 are made conductive. As a result, the connection between the MIO line MIOT and the LIO line LIOT is in an conduction state, and the connection between the MIO line MIOB and the LIO line LIOB is in an conduction state. The pair of LIO lines LIOT/B is set to complementary voltage levels that are the same as those of the pair of MIO lines MIOT/B. The bit line BLT is connected to the LIO line LIOT and the bit line BLB is connected to the LIO line LIOB via the switch (formed of the NMOS transistors 501 and 502 in FIG. 5) for which the column selection signal YS is set to High. The sense amplifier (SA) connected to the pair of bit lines BLT and BLB performs differential amplification, and a write to the memory cell MC connected to the selected word line WL is performed.

When a read operation is performed, the write amplifier (composed by the transistors 901 to 904 in FIG. 8 and shown in FIG. 13) is brought into an off state (output disable state). When the column selection signal YS is selected, the column switch (composed by the NMOS transistors 501 and 502 in FIG. 5) is made conductive. Then, electric charge of the LIO line (LIOT or LIOB) connected to the bit line (BLT or BLB) in a Low state is discharged. A difference in voltage level between the LIO lines LIOT and LIOB is thereby generated. A difference is thereby generated at gate voltages of NMOS transistors 406 and 407 that respectively receive the LIO lines LIOT and LIOB at gates thereof at the SWC in FIG. 10. Drains of the NMOS transistors 406 and 407 are respectively connected to the pair of MIO lines MIOB and MIOT. When the signal DIORET transitions to High, all of NMOS transistors 403, 404, and 405 are made conductive, and a source voltage of each of the NMOS transistors 406 and 407 assumes a low-potential power supply voltage VSS. Due to the difference in voltage-level generated between the LIO lines LIOT and LIOB, the NMOS transistors 406 and 407 complementarily drive the MIO lines MIOT and MIOB. A difference in voltage-level between the MIO lines MIOT and MIOB is amplified to a CMOS level amplitude by a read amplifier in the main amplifier (MA) 302 in FIG. 3.

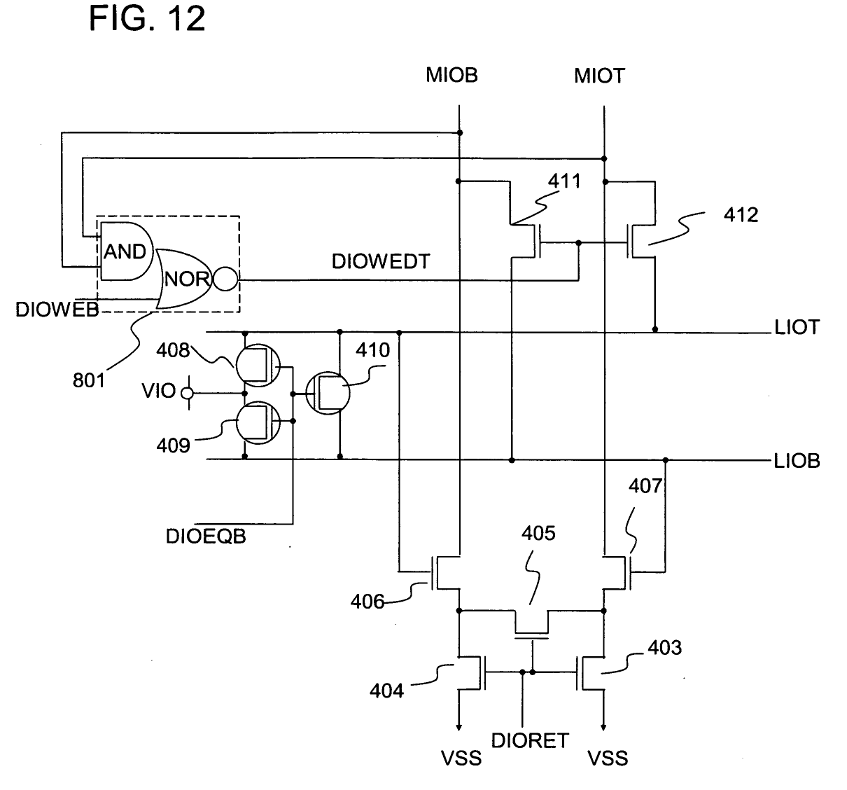

Next, a variation of the above-mentioned embodiment will be described as another embodiment of the present invention. In the another embodiment, the CMOS pass gates 401 and 402 in FIG. 10 are changed to NMOS transistors 411 and 412, as shown in FIG. 12. An output DIOWEDT of an NOR circuit in a logic circuit 801 is connected in common to gates of the NMOS transistors 411 and 412. The NMOS transistor 411 is connected between an MIO line MIOB and an LIO line LIOB, and the NMOS transistor 412 is connected between an MIO line MIOT and an LIO line LIOT. In this case, the gates of the PMOS transistors of the pass gates do not need to be driven. Thus, a circuit configuration is further simplified. An operation of the circuit shown in FIG. 12 is substantially the same as that of the circuit in FIG. 10.

In this embodiment, a sub-amplifier circuit for reading (composed by the transistors 406, 407, 403, 404, and 405 in FIG. 10) is arranged between the pair of LIO lines LIOT/B and the pair of MIO lines MIOT/B. The sense amplifier (SA) should thereby only discharge electric charge of the pair of LIO lines LIOT/B. Thus, even the sense amplifier (SA) having a small current driving capability can perform a high-speed read operation.

In a write operation at a time of write masking in this embodiment, the pass gates of the MIO lines to which data will not be written is closed. When a YS signal is High, the parasitic capacitance seen from the sense amplifier are limited only to the parasitic capacitance of the LIO lines. Rising of the Low level of the bit line and falling of the High level of the bit line can be reduced. The collapse of data held in a memory cell can be thereby prevented. That is, the MIO lines do not disturb the potentials of the LIO lines nor disturb data refreshed by the sense amplifier. Reliability of data holding in the sense amplifier can be thereby enhanced.

The basic technical concept of this application is not limited to what was described herein. For example, the DRAM was disclosed in the example. The basic technical concept of this application is not limited to this, and an SRAM (static random access memory) or another synchronous-type memory, for example, may be used. Further, circuit forms such as the sense amplifier, write amplifier, each equalization circuit provided for each hierarchy, and sub-amplifier attached to the hierarchical switches are not of course limited to the circuit forms disclosed in the example. Voltage control values on each associated hierarchy controlled by each equalizing circuit are not limited to those disclosed in the example. For equalizing on the secondary hierarchy, a low potential or an intermediate potential between a high potential Vdd and the low potential may be used, in addition to the high potential Vdd disclosed in the example. In this case, by forming the switch control circuit using a comparison circuit (voltage comparison circuit) that employs the intermediate voltage as a reference voltage and an output signal of the comparison circuit, the effect of this application is achieved. Those skilled in the art can readily understand achievement of the effect, based on the basic technical concept of this application.

This example may be applied to a semiconductor device such as an SOC (system-on-chip), an MCP (multi-chip package), or a POP (package-on-package).

Further, the invention can be applied to a semiconductor device having a logic function and memory cells, and a semiconductor device such as a CPU, an MCU, or a DSP. The transistor may be a field effect transistor (Field Effect Transistor: FET). The invention can be applied to various FETs such as an MIS (Metal-Insulator Semiconductor) transistor, a TFT (Thin Film Transistor), in addition to the MOS (Metal Oxide Semiconductor) transistor. The invention can be applied to various FETs such as the transistor. The transistor may be a bipolar transistor. The transistor may be the one other than the FET. Further, the NMOS transistor (N-type channel MOS transistor) is a typical example of a first conductivity type transistor, while the PMOS transistor (P-type channel MOS transistor) is a typical example of a second conductivity type transistor.

<Contrast with Patent Document 1>

The data bus in Patent Document 1 is not a bidirectional complementary data bus that performs a read and a write. Further, the latch circuits in Patent Document 1 are configured to only hold data on the data lines DB and /DB (immediately preceding data). When data subsequent to the data on the data lines DB and /DB is supplied via the transfer gates, the immediately preceding data is erased. Accordingly, after equalizing, latched data is broken (written). In Patent Document 1, data bus pairs in at least two systems and those systems do not differently operate according to a mask signal. As described above, Patent Document 1 is completely different from the above-mentioned present invention. The sense amplifier connected to the MIO pair of data lines for which write masking (data masking) has been performed must not be used for writing inverted data as shown in FIG. 7D. According to the present invention, at a time of write masking (data masking), the pair of MIO lines does not disturb potentials of the pair of LIO lines, and secures data held in a memory cell (user data safety). The present invention is completely different from Patent Document 1 in this respect as well.

Modifications and adjustments of the exemplary embodiments and the examples are possible within the scope of the overall disclosure (including claims) of the present invention, and based on the basic technical concept of the invention. Various combinations and selections of various disclosed elements are possible within the scope of the claims of the present invention. That is, the present invention of course includes various variations and modifications that could be made by those skilled in the art according to the overall disclosure including the claims and the technical concept.

What is claimed is:

1. A semiconductor device comprising:
a pair of primary data lines having one or more memory cells connected thereto, the pair of primary data lines transferring data bidirectionally;
a pair of secondary data lines transferring data bidirectionally;
a switch controlling connection between the pair of primary data lines and the pair of secondary data lines,
the pair of secondary data lines being connected via the switch to the pair of primary data lines to output internal data information held by the memory cell to an outside, the pair of secondary data lines receiving external data information from the outside;
a primary amplifier connected to the pair of primary data lines, the primary amplifier amplifying and holding the data information on the pair of primary data lines;
a secondary amplifier connected to the pair of secondary data lines; and
a switch control circuit controlling the switch,
when writing data to the memory cell, the secondary amplifier driving the pair of secondary data lines in correspondence with the external data information, the data information on the pair of secondary data lines being transferred to the pair of primary data lines via the switch in a conduction state, and the internal data information held by the primary amplifier being rewritten by the external data information,
the switch control circuit performing control so as to make the switch conductive when two data lines constituting the pair of secondary data lines assume voltages different in logic level from each other, the switch control circuit performing control so as to make the switch non-conductive when the two data lines constituting the pair of secondary data lines assume a same predetermined voltage.

2. The semiconductor device according to claim 1, further comprising:
an equalization circuit connected between the two data lines constituting the pair of secondary data lines;
the equalization circuit setting the two data lines constituting the pair of secondary data lines to the same predetermined voltage, before the secondary-amplifier operates.

3. The semiconductor device according to claim 1, wherein a capacitance value of a parasitic capacitance of the pair of secondary data lines is larger than a capacitance value of a parasitic capacitance of the pair of primary data lines.

4. The semiconductor device according to claim 1, wherein a driving capability of the secondary amplifier is larger than a driving capability of the primary amplifier.

5. The semiconductor device according to claim 1, wherein the switch control circuit is supplied with a write mode signal for activating the secondary amplifier to write the external data information to the memory cell.

6. The semiconductor device according to claim 5, wherein the semiconductor device includes:
a first data bus system and a second data bus system each comprising the pair of primary data lines, the pair of secondary data lines, the switches corresponding to the pairs of primary and secondary data lines, the primary amplifier, and the secondary amplifier; and
first and second mask signal respectively corresponding to the first data bus system and the second data bus system;
the write mode signal and the first mask signal being supplied to a write amplifier of the secondary amplifier in the first data bus system,
the write mode signal and the second mask signal being supplied to a write amplifier of the secondary amplifier in the second data bus system, and
the first and second mask signals respectively controlling the corresponding the write amplifiers of the secondary amplifiers in the first and second data bus systems to be deactivated, without dependence on control of the write mode signal.

7. The semiconductor device according to claim 6, wherein the two data lines constituting the pair of secondary data lines corresponding to the write amplifier controlled to be deactivated assume the same predetermined voltage.

8. The semiconductor device according to claim 5, wherein the switch control circuit controls to make the switch non-conductive when the write mode signal is inactive, the semiconductor device comprising
a sub-amplifier that receives the data information on the pair of primary data lines and drives the pair of secondary data lines through a route different from the switch to transfer the data information in the memory cell from the pair of primary data lines to the pair of secondary data lines.

9. A semiconductor device comprising:
a complementary first pair of data lines, a complementary second pair of data lines, and a complementary third pair of data lines, in each of which one signal is represented by complementary signals;
a first amplifier connected to the complementary first pair of data lines;
a first switch controlling connection between the complementary first pair of data lines and the complementary second pair of data lines;
a second switch controlling connection between the complementary second pair of data lines and the complementary third pair of data lines;
a second amplifier amplifying data on the complementary second pair of data lines to output the amplified data to the complementary third pair of data lines;
a third amplifier connected to the complementary third pair of data lines; and
a switch control circuit controlling the second switch, the switch control circuit performing control so as to make the second switch non-conductive when two data lines constituting the complementary third pair of data lines are both in a first state, the second switch thus controlling the complementary second pair of data lines and the complementary third pair of data lines to be electrically disconnected, output data of the first amplifier being output to the complementary second pair of data lines via the first switch at a time of electrical disconnection between the complementary second pair of data lines and the complementary third pair of data lines,
the switch control circuit performing control so as to make the second switch conductive when the two data lines constituting the complementary third pair of data lines are both in a second state which is different from the first state according to data corresponding to external data information supplied from an outside and output by the third amplifier,
the second switch controlling the complementary second pair of data lines and the complementary third pair of data lines to be electrically connected, the first amplifier receiving the data output by the third amplifier.

10. The semiconductor device according to claim 9, further comprising:
an equalization circuit that sets the two data lines constituting the complementary third pair of data lines to a same predetermined voltage,
the complementary third pair of data lines being controlled to be in the first state by the equalization circuit.

11. The semiconductor device according to claim 9, wherein a parasitic capacitance value of the complementary third pair of data lines is larger than a parasitic capacitance value of the complementary second pair of data lines.

12. A semiconductor device comprising:
first pair of data lines and second pair of data lines, on each of which bidirectional complementary data transfer is performed;
a first switch that controls conduction and non-conduction between the first pair of data lines and the second pair of data lines;
a first amplifier including a write amplifier that receives write data corresponding to external data information and supplied from an outside, and that drives two data lines constituting the first pair of data lines to mutually different voltage levels;
an equalization circuit that precharges and sets two data lines constituting the first pair of data lines to a same predetermined voltage before the first amplifier operates;
a logic circuit that receives as inputs the two data lines constituting the first pair of data lines and a write mode signal, the logic circuit performing control to make the first switch conductive when the write mode signal is active and voltages of the two data lines assumes voltages different in logic level from each other, the logic circuit performing control to make the first switch conductive when the write mode signal is inactive or the two data lines assume the same predetermined voltage;
a second switch controlled to be made conductive on and non-conductive by a selection signal;
a third pair of data lines connected to the second pair of data lines via the second switch;
a memory cell connected to the third pair of data lines, the external data information written into the memory cell being stored in the memory cell, while the external data information stored in the memory cell being read from the memory cell; and
a second amplifier connected to the third pair of data lines, the second amplifier amplifying data on the third pair of data lines read from the memory cell,
when the data is written into the memory cell, a first one of the write amplifier corresponding to the write data for which write masking is specified being deactivated or made non-conductive with respect to the first pair of data lines corresponding to the first one of the write amplifier, the logic circuit corresponding to the first write amplifier controlling to make the first switch non-conductive in response to the mutually same predetermined voltage of the two data lines constituting the first pair of data lines set by the equalization circuit in advance, thereby disconnecting the first and second pair of data lines corresponding to the first write amplifier;
the second pair of data lines corresponding to the first write amplifier being driven by the second amplifier via the second switch selected and controlled to be on by the selection signal, the second amplifier amplifying the data stored in the memory cell.

13. The semiconductor device according to claim 12, wherein when the data is written, a second one of the write amplifier corresponding to the write data for which the write masking is not specified drives the two data lines constituting the first pair of data lines set to the predetermined voltage by the equalization circuit, to voltages mutually different in logic level, corresponding to the write data signal,
the logic circuit corresponding to the second write amplifier controls to make the first switch conductive, in response to the write mode signal being active and the two data line assuming the mutually differential voltages; and
the write data is transferred from the first pair of data lines corresponding to the second write amplifier to the second pair of data lines corresponding to the second write amplifier via the first switch controlled to be made conductive,
the data being further transferred to the third pair of data lines corresponding to the second write amplifier from the second pair of data lines corresponding to the second write amplifier via the second switch selected and controlled to be made conductive by the selection signal, the data transferred to the third pair of data lines corresponding to the second write amplifier being amplified by the second amplifier to be written into the memory cell selected.

14. The semiconductor device according to claim 13, wherein non-conduction control of the first switch corresponding to the first write amplifier and non-conduction control of the first switch corresponding to the second write amplifier are executed in a same data write cycle,
the second pair of data lines corresponding to the first write amplifier for which the write masking is specified indicating data in the memory cell for which writing is inhibited; and
the second pair of data lines corresponding to the second write amplifier for which the write masking is not specified indicates the write data supplied from the outside which is written from the outside.

15. The semiconductor device according to claim 12, further comprising:
a third amplifier that receives signals of the second pair of data lines and drives the two data lines constituting the first pair of data lines to voltages different in logic level from each other, corresponding to the information in the memory cell through a route different from the first switch;
when the data is read from the memory cell, the write mode signal being deactivated, and the write amplifier of the first amplifier being deactivated or non-conductive,
the logic circuit controlling the first switch to be non-conductive in response to the deactivated write mode signal,
the data in the memory cell selected being amplified by the second amplifier and then being transferred to the second pair of data lines via the second switch controlled to be turned on by the selection signal, being further amplified by the third amplifier to be transferred to the first pair of data lines, then amplified by a read amplifier included in the first amplifier that amplifies signals of the first pair of data lines, and then being output to the outside.
